(19) United States
(12) Patent Application Publication
(10) Pub. No.: US 2024/0302747 A1
(43) Pub. Date: Sep. 12, 2024

(54) NAPHTHALENE UNIT-CONTAINING RESIST UNDERLAYER FILM-FORMING COMPOSITION

(71) Applicant: NISSAN CHEMICAL CORPORATION, Tokyo (JP)

(72) Inventors: Hiroto OGATA, Toyama-shi (JP); Ryuta MIZUOCHI, Toyama-shi (JP); Tomotada HIROHARA, Toyama-shi (JP); Mamoru TAMURA, Toyama-shi (JP)

(73) Assignee: NISSAN CHEMICAL CORPORATION, Tokyo (JP)

(21) Appl. No.: 18/281,993

(22) PCT Filed: Mar. 15, 2022
(86) PCT No.: PCT/JP2022/011508

§ 371 Date: Sep. 14, 2023

(30) Foreign Application Priority Data
Mar. 16, 2021 (JP) 2021-042228

(51) Int. Cl. G03F 7/11; G03F 7/16; G03F 7/20; H01L 21/027; H01L 21/308

(52) U.S. Cl. CPC G03F 7/11; G03F 7/168; G03F 7/2004; H01L 21/0275; H01L 21/3081; H01L 21/3086

(57) ABSTRACT

A composition for forming a resist underlayer film that enables the formation of a desired resist pattern; a method for producing a resist pattern, the method using this resist underlayer film-forming composition; and a method for producing a semiconductor device. The resist underlayer film-forming composition includes a solvent and a product of reaction between compound (A) represented by formula (100) below. In formula (100), Ar1 and Ar2 each independently represent a C6-C40 aromatic ring that may be substituted, at least one of Ar1 and Ar2 is a naphthalene ring, L1 represents a single bond, a C1-C10 alkylene group that may be substituted, or a C2-C10 alkenylene group that may be substituted, T1 and T2 each independently represent a single bond, an ester bond or an ether bond, and E represents an epoxy group) and compound (B) containing at least two groups having reactivity with an epoxy group.

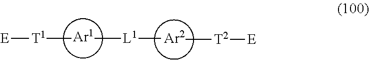

### TECHNICAL FIELD

The present invention relates to a composition for use in lithography processes for the manufacture of a semiconductor, in particular in state-of-the-art (ArF, EUV, EB, etc.) lithography processes. The present invention also relates to a method for producing a substrate with a resist pattern to which the resist underlayer film is applied, and a method for producing a semiconductor device.

### BACKGROUND ART

Conventionally, fine processing by lithography using a resist composition has been performed in the manufacture of semiconductor devices. The fine processing is a processing method of forming fine unevenness corresponding to a pattern on a substrate surface by forming a thin film of a photoresist composition on a semiconductor substrate such as a silicon wafer, irradiating the thin film with an active ray such as an ultraviolet ray through a mask pattern having a device pattern drawn thereon, developing the thin film, and etching the substrate using the obtained photoresist pattern as a protective film. In recent years, semiconductor devices have become more highly integrated, and in addition to i-line (wavelength: 365 nm), KrF excimer laser (wavelength: 248 nm), and ArF excimer laser (wavelength: 193 nm) that have been conventionally used, practical application of EUV light (wavelength: 13.5 nm) or electron beam (EB) has been studied for the most advanced fine processing. Accordingly, resist pattern formation defects due to influences from semiconductor substrates or the like have become a major problem. Therefore, in order to solve this problem, a method of providing a resist underlayer film between a resist and a semiconductor substrate has been widely studied. Patent Literature 1 discloses a resist underlayer film-forming composition for EUV lithography containing a condensation polymer. Patent Literature 2 discloses an organic film material for forming an organic film having dry etching resistance and also having advanced embedding/planarization properties.

### CITATION LIST

### Patent Literature

Patent Literature 1: WO 2013/018802 A
Patent Literature 2: JP 2016-216367 A

### SUMMARY OF INVENTION

### Technical Problem

The properties required for a resist underlayer film include, for example, that the film does not cause intermixing with the resist film formed on the upper layer (that is, the resist underlayer film is insoluble in a resist solvent).

In the case of lithography involving EUV exposure, the line width of a resist pattern to be formed is 32 nm or less, and a resist underlayer film for EUV exposure is formed to be thinner than conventional one. When forming such thin films, pinholes, agglomerations, and other defects are likely to occur due to the influence of the substrate surface, polymers used, and other factors, making it difficult to form a uniform film without defects.

On the other hand, in a negative development process, which removes the unexposed portions of the resist film and leaves the exposed portions of the resist film as the resist pattern, or in the positive development process, which removes the exposed portions of the resist film and leaves the unexposed portions of the resist film as the resist pattern, using a solvent, usually an organic solvent, that can dissolve the resist film in the development process when forming a resist pattern, improving the adhesion of the resist pattern is a major issue.

In addition, it is required to suppress deterioration of LWR (line width roughness, fluctuation in line width (roughness)) during resist pattern formation, to form a resist pattern having a favorable rectangular shape, and to improve resist sensitivity.

An object of the present invention is to provide a composition for forming a resist underlayer film capable of forming a desired resist pattern, and a method for forming a resist pattern using the resist underlayer film-forming composition, which have solved the above problems.

### Solution to Problem

The present invention includes the followings.

[1]

A resist underlayer film-forming composition comprising
a solvent and
a reaction product of a compound (A) represented by the following formula (100):

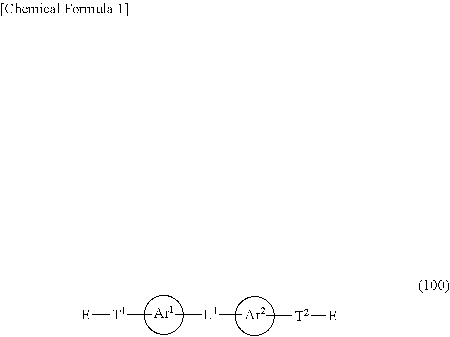

(in the formula (100), Ar¹ and Ar² each independently represent an optionally substituted aromatic ring having 6 to 40 carbon atoms, and at least one of Ar¹ and Ar² is a naphthalene ring; L¹ represents a single bond, an optionally substituted alkylene group having 1 to 10 carbon atoms, or an optionally substituted alkenylene group having 2 to 10 carbon atoms; T¹ and T² each independently represent a single bond, an ester bond, or an ether bond; and E represents an epoxy group) with a compound (B) containing at least two groups having reactivity with an epoxy group.
   [2]

The resist underlayer film-forming composition according to [1], wherein the compound (B) contains a heterocyclic ring structure or an aromatic ring structure having 6 to 40 carbon atoms.

[3]

The resist underlayer film-forming composition according to [1] or [2], wherein the compound (B) is represented by the following formula (101):

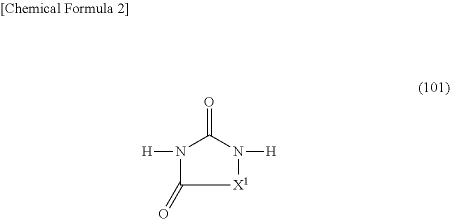

(in the formula (101), X¹ is represented by the following formula (2), formula (3), formula (4), or formula (0):

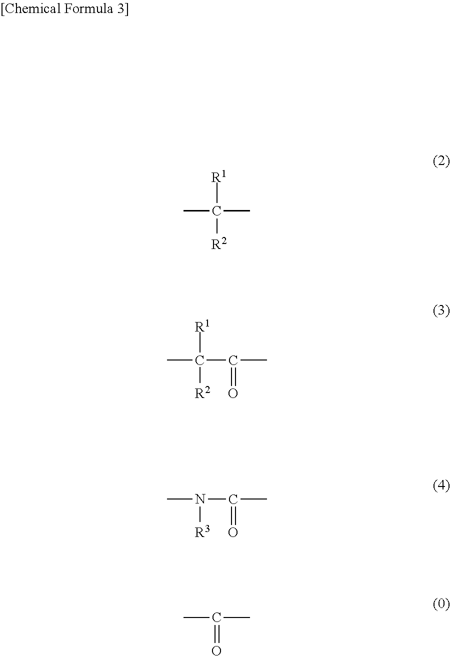

(in the formulae (2), (3), (4) and (0), R¹ and R² each independently represent a hydrogen atom, a halogen atom, an alkyl group having 1 to 10 carbon atoms, an alkenyl group having 2 to 10 carbon atoms, a benzyl group, or a phenyl group, and the alkyl group having 1 to 10 carbon atoms, the alkenyl group having 2 to 10 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 10 carbon atoms, and R¹ and R² may be bonded to each other to form a ring having 3 to 10 carbon atoms; R³ represent a halogen atom, an alkyl group having 1 to 10 carbon atoms, an alkenyl group having 2 to 10 carbon atoms, a benzyl group, or a phenyl group, and the phenyl group may be substituted with a group selected from the group consisting of an alkyl group having 1 to 10 carbon atoms, a halogen atom, an alkoxy group having 1 to 10 carbon atoms, a nitro group, a cyano group, a hydroxy group, and an alkylthio group having 1 to 10 carbon atoms).

[4]

The resist underlayer film-forming composition according to any one of [1] to [3], wherein the reaction product has a terminal comprising a structure represented by the following formula (102):

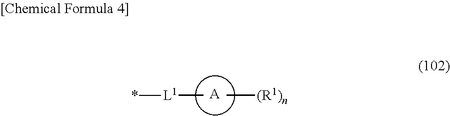

(in the formula (102), Ar represents an optionally substituted aromatic ring having 6 to 40 carbon atoms; L¹ represents an ester bond, an ether bond, or an optionally substituted alkenylene group having 2 to 10 carbon atoms; n quantity of R¹ independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a bonding site to the reaction product).

[5]

The resist underlayer film-forming composition according to any one of [1] to [4], further comprising an acid generator.

[6]

The resist underlayer film-forming composition according to any one of [1] to [5], further comprising a crosslinking agent.

[7]

The resist underlayer film-forming composition according to any one of [1] to [6], which is for an extreme ultraviolet (EUV) exposure process.

[8]

A resist underlayer film, which is a baked product of a coating film of the resist underlayer film-forming composition according to any one of [1] to [7].

[9]

A method for producing a patterned substrate, comprising the steps of:
applying the resist underlayer film-forming composition according to any one of [1] to [7] onto a semiconductor substrate followed by baking to form a resist underlayer film;
applying a resist onto the resist underlayer film followed by baking, to form a resist film;
exposing the semiconductor substrate coated with the resist underlayer film and the resist; and
developing and patterning the exposed resist film.
   [10]

A method for producing a semiconductor device, comprising the steps of:
forming a resist underlayer film of the resist underlayer film-forming composition of any one of [1] to [7] on a semiconductor substrate;
forming a resist film on the resist underlayer film;
forming a resist pattern by irradiating the resist film with a light or electron beam followed by development;
forming a patterned resist underlayer film by etching the resist underlayer film through the formed resist pattern, and
processing the semiconductor substrate with the patterned resist underlayer film.

### Advantageous Effects of Invention

Attributable to a naphthalene ring unit contained in the polymer, the resist underlayer film-forming composition of the present invention has excellent application property to a semiconductor substrate to be processed, and provides excellent adhesion between a resist and a resist underlayer film interface during resist pattern formation. This leads to suppressing the deterioration of LWR (line width roughness, line width fluctuation (roughness)) during resist pattern formation without causing resist pattern peeling, minimizing the resist pattern size (minimum CD size), and forming a good resist pattern that is rectangular in shape. In particular, remarkably advantageous effects are exhibited when EUV (wavelength 13.5 nm) or EB (electron beam) is used.

### DESCRIPTION OF EMBODIMENTS

### <Resist Underlayer Film-Forming Composition>

The resist underlayer film-forming composition of the present invention contains a solvent and a reaction product of a compound (A) represented by the following formula (100):

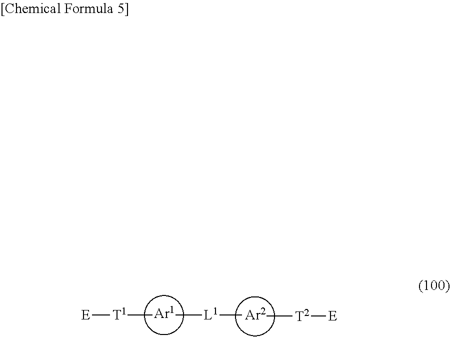

(in the formula (100), Ar¹ and Ar² each independently represent an optionally substituted aromatic ring having 6 to 40 carbon atoms, and at least one of Ar¹ and Ar² is a naphthalene ring; L¹ represents a single bond, an optionally substituted alkylene group having 1 to 10 carbon atoms, or an optionally substituted alkenylene group having 2 to 10 carbon atoms; T¹ and T² each independently represent a single bond, an ester bond, or an ether bond; and E represents an epoxy group) with a compound (B) containing at least two groups having reactivity with an epoxy group.

By reacting the compound (A) with the compound (B), for example, by a known method described in Examples, a reaction product (polymer) of the compound (A) with the compound (B) can be produced.

Examples of the aromatic ring having 6 to 40 carbon atoms include benzene, naphthalene, anthracene, acenaphthene, fluorene, triphenylene, phenalene, phenanthrene, indene, indane, indacene, pyrene, chrysene, perylene, naphthacene, pentacene, coronene, heptacene, benzo[a]anthracene, dibenzophenanthrene, and dibenzo[a,j]anthracene.

Examples of the alkylene group having 1 to 10 carbon atoms include methylene, ethylene, n-propylene, sopropylene, cyclopropylene, n-butylene, isobutylene, s-butylene, t-butylene, cyclobutylene, 1-methyl-cyclopropylene, 2-methyl-cyclopropylene, n-pentylene, 1-methyl-n-butylene, 2-methyl-n-butylene, 3-methyl-n-butylene, 1,1-dimethyl-n-propylene, 1,2-dimethyl-n-propylene, 2,2-dimethyl-n-propylene, 1-ethyl-n-propylene, cyclopentylene, 1-methyl-cyclobutylene, 2-methyl-cyclobutylene, 3-methyl-cyclobutylene, 1,2-dimethyl-cyclopropylene, 2,3-dimethyl-cyclopropylene, 1-ethyl-cyclopropylene, 2-ethyl-cyclopropylene, n-hexylene, 1-methyl-n-pentylene, 2-methyl-n-pentylene, 3-methyl-n-pentylene, 4-methyl-n-pentylene, 1,1-dimethyl-n-butylene, 1,2-dimethyl-n-butylene, 1,3-dimethyl-n-butylene, 2,2-dimethyl-n-butylene, 2,3-dimethyl-n-butylene, 3,3-dimethyl-n-butylene, 1-ethyl-n-butylene, 2-ethyl-n-butylene, 1,1,2-trimethyl-n-propylene, 1,2,2-trimethyl-n-propylene, 1-ethyl-1 methyl-n-propylene, 1-ethyl-2-methyl-n-propylene, cyclohexylene, 1-methyl-cyclopentylene, 2-methyl-cyclopentylene, 3-methyl-cyclopentylene, 1-ethyl-cyclobutylene, 2-ethyl-cyclobutylene, 3-ethyl-cyclobutylene, 1,2-dimethyl-cyclobutylene, 1,3-dimethyl-cyclobutylene, 2,2-dimethyl-cyclobutylene, 2,3-dimethyl-cyclobutylene, 2,4-dimethyl-cyclobutylene, 3,3-dimethyl-cyclobutylene, 1-n-propyl-cyclopropylene, 2-n-propyl-cyclopropylene, 1-isopropyl-cyclopropylene, 2-isopropyl-cyclopropylene, 1,2,2-trimethyl-cyclopropylene, 1,2,3-trimethyl-cyclopropylene, 2,2,3-trimethyl-cyclopropylene, 1-ethyl-2-methyl-cyclopropylene, 2-ethyl-1-methyl-cyclopropylene, 2-ethyl-2-methyl-cyclopropylene, 2-ethyl-3-methyl-cyclopropylene, n-heptylene, n-octylene, n-nonylene, and n-decanylene groups.

Examples of the alkenylene group having 2 to 10 carbon atoms include, out of the above-described alkylene groups having 2 to 10 carbon atoms, groups having at least one double bond in which hydrogen atoms are each removed from adjacent carbon atoms. Of the alkenylene groups having 2 to 10 carbon atoms, a vinylene group is preferable.

The phrase “optionally substituted” means that some or all of hydrogen atoms present in the alkylene group having 1 to 10 carbon atoms or the alkenylene group having 2 to 10 carbon atoms may be substituted with, for example, a hydroxy group, a halogen atom, a carboxyl group, a nitro group, a cyano group, a methylenedioxy group, an acetoxy group, a methylthio group, an amino group, an alkyl group having 1 to 10 carbon atoms, or an alkoxy group having 1 to 10 carbon atoms.

Examples of the alkyl group having 1 to 10 carbon atoms include methyl, ethyl, n-propyl, i-propyl, cyclopropyl, n-butyl, i-butyl, s-butyl, t-butyl, cyclobutyl, 1-methyl-cyclopropyl, 2-methyl-cyclopropyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, cyclopentyl, 1-methyl-cyclobutyl, 2-methyl-cyclobutyl, 3-methyl-cyclobutyl, 1,2-dimethyl-cyclopropyl, 2,3-dimethyl-cyclopropyl, 1-ethyl-cyclopropyl, 2-ethyl-cyclopropyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2-trimethyl-n-propyl, 1,2,2-trimethyl-n-propyl, 1-ethyl-1-methyl-n-propyl, 1-ethyl-2-methyl-n-propyl, cyclohexyl, 1-methyl-cyclopentyl, 2-methyl-cyclopentyl, 3-methyl-cyclopentyl, 1-ethyl-cyclobutyl, 2-ethyl-cyclobutyl, 3-ethyl-cyclobutyl, 1,2-dimethyl-cyclobutyl, 1,3-dimethyl-cyclobutyl, 2,2-dimethyl-cyclobutyl, 2,3-dimethyl-cyclobutyl, 2,4-dimethyl-cyclobutyl, 3,3-dimethyl-cyclobutyl, 1-n-propyl-cyclopropyl, 2-n-propyl-cyclopropyl, 1-i-propyl-cyclopropyl, 2-i-propyl-cyclopropyl, 1,2,2-trimethyl-cyclopropyl, 1,2,3-trimethyl-cyclopropyl, 2,2,3-trimethyl-cyclopropyl, 1-ethyl-2-methyl-cyclopropyl, 2-ethyl-1-methyl-cyclopropyl, 2-ethyl-2-methyl-cyclopropyl, 2-ethyl-3-methyl-cyclopropyl, and decyl groups.

Examples of the alkoxy group having 1 to 10 carbon atoms include methoxy, ethoxy, n-propoxy, i-propoxy, n-butoxy, i-butoxy, s-butoxy, t-butoxy, n-pentoxy, 1-methyl-n-butoxy, 2-methyl-n-butoxy, 3-methyl-n-butoxy, 1,1-dimethyl-n-propoxy, 1,2-dimethyl-n-propoxy, 2,2-dimethyl-n-propoxy, 1-ethyl-n-propoxy, n-hexyloxy, 1-methyl-n-pentyloxy, 2-methyl-n-pentyloxy, 3-methyl-n-pentyloxy, 4-methyl-n-pentyloxy, 1,1-dimethyl-n-butoxy, 1,2-dimethyl-n-butoxy, 1,3-dimethyl-n-butoxy, 2,2-dimethyl-n-butoxy, 2,3-dimethyl-n-butoxy, 3,3-dimethyl-n-butoxy, 1-ethyl-n-butoxy, 2-ethyl-n-butoxy, 1,1,2-trimethyl-n-propoxy, 1,2,2-trimethyl-n-propoxy, 1-ethyl-1-methyl-n-propoxy, 1-ethyl-2-methyl-n-propoxy, n-heptyloxy, n-octyloxy, n-nonyloxy, and n-decanyloxy groups.

The compound (A) may be a commercially available compound having two epoxy groups containing at least a naphthalene substructure and exhibiting the advantageous effects of the present invention. Specific examples thereof include EPICLON HP-4770, HP-6000, and WR-600 (all manufactured by DIC Corporation).

The compound (A) may be a compound having two epoxy groups and having the following general formula described in JP 2007-262013 A:

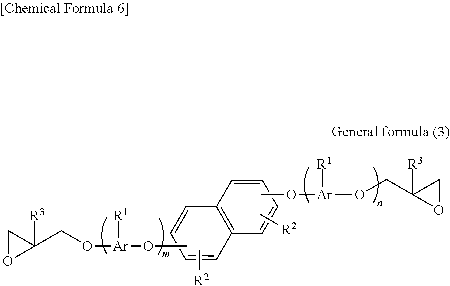

(in the formula (3), R³ represents a hydrogen atom or a methyl group, Ar each independently represents a naphthylene group, a phenylene group, or a naphthylene or phenylene group having an alkyl group having 1 to 4 carbon atoms or a phenyl group as a substituent; R² each independently represents a hydrogen atom or an alkyl group having 1 to 4 carbon atoms; n and m each represent an integer of 0 to 2, either n or m is 1 or more; and R¹ represents a hydrogen atom or an epoxy group-containing aromatic hydrocarbon group represented by the following general formula (3-2); provided that the total number of aromatic nuclei in the formula is 2 to 8; and, in the general formula (3), the bonding position to the naphthalene skeleton may be any of the two nuclei constituting the naphthalene ring);

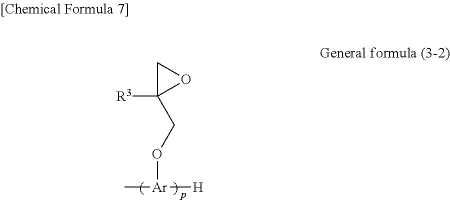

(in the general formula (3-2), R³ represents a hydrogen atom or a methyl group; Ar each independently represents a naphthylene group, a phenylene group, or a naphthylene or phenylene group having an alkyl group having 1 to 4 carbon atoms or a phenyl group as a substituent; and p is an integer of 1 or 2).

The compounds represented by the formula (100) and the general formula (3) may be contained, for example, in an amount of 10% by mass or more, 30% by mass or more, or 50% by mass or more in the solid content contained in the resist underlayer film-forming composition of the present invention.

Specific examples of the compound (B) containing at least two groups reactive with an epoxy group include the compounds below.

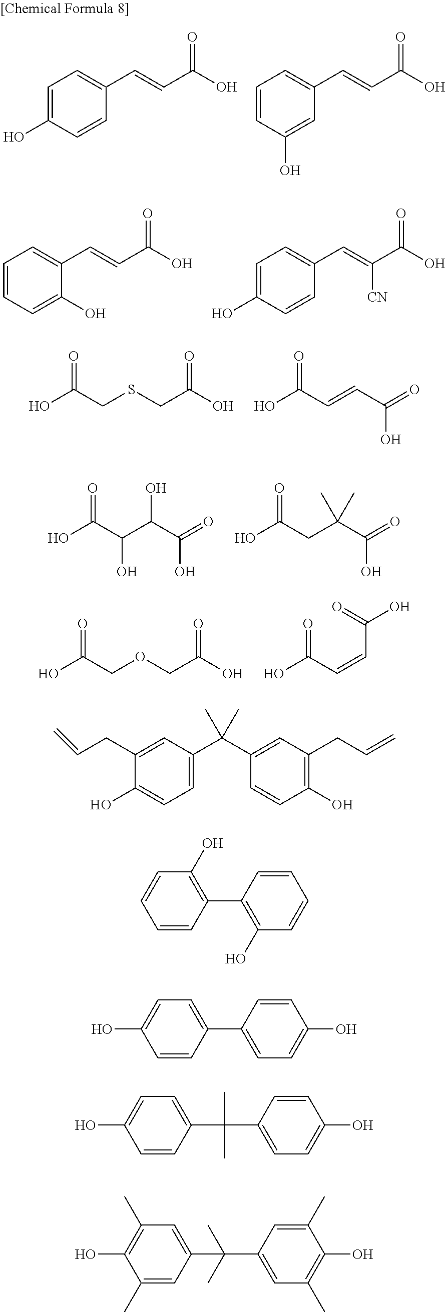

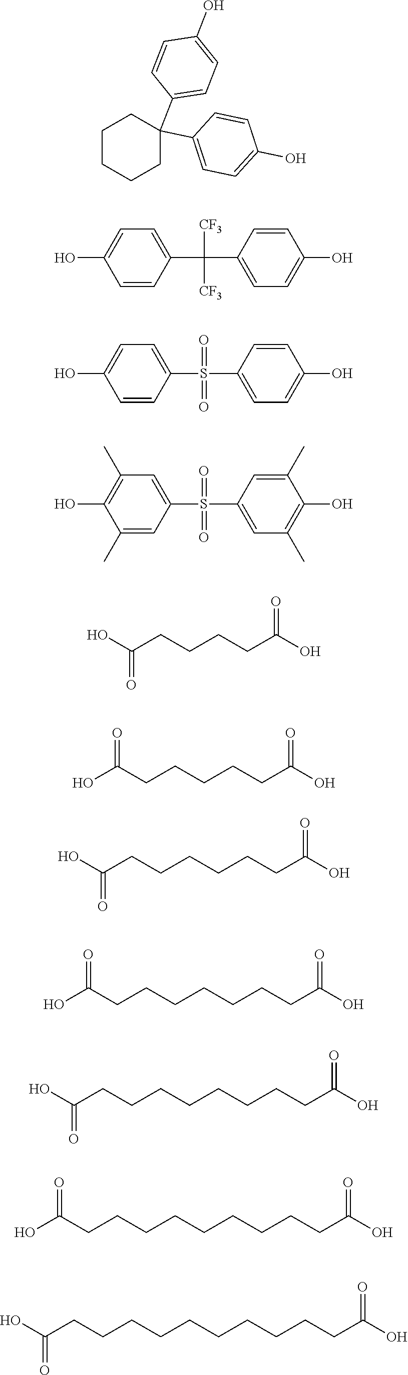

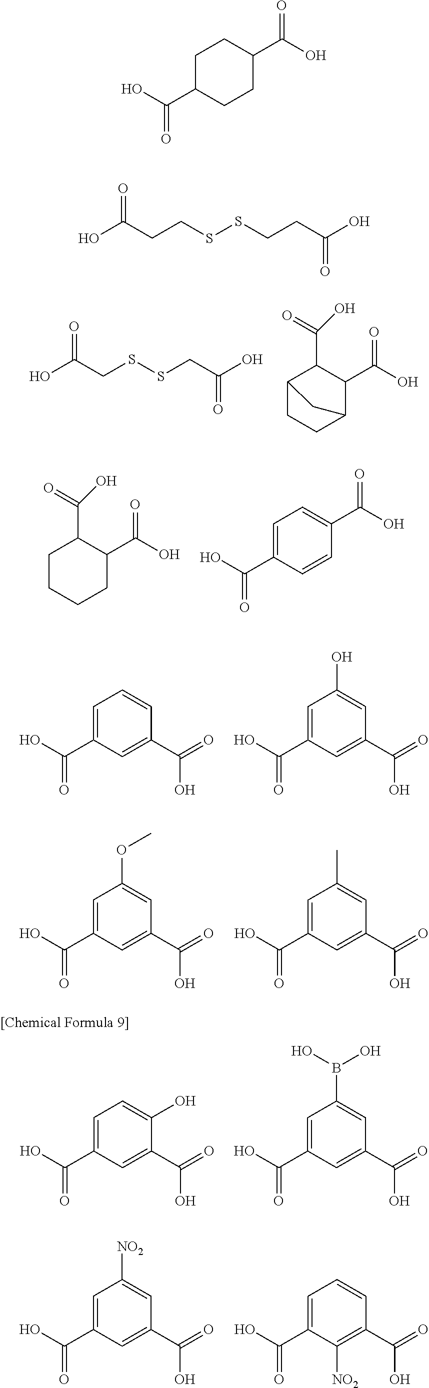

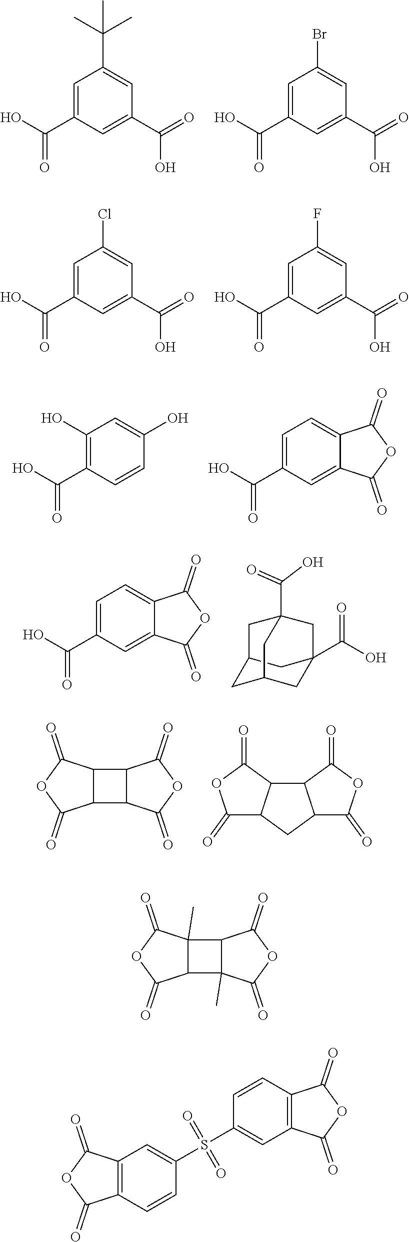

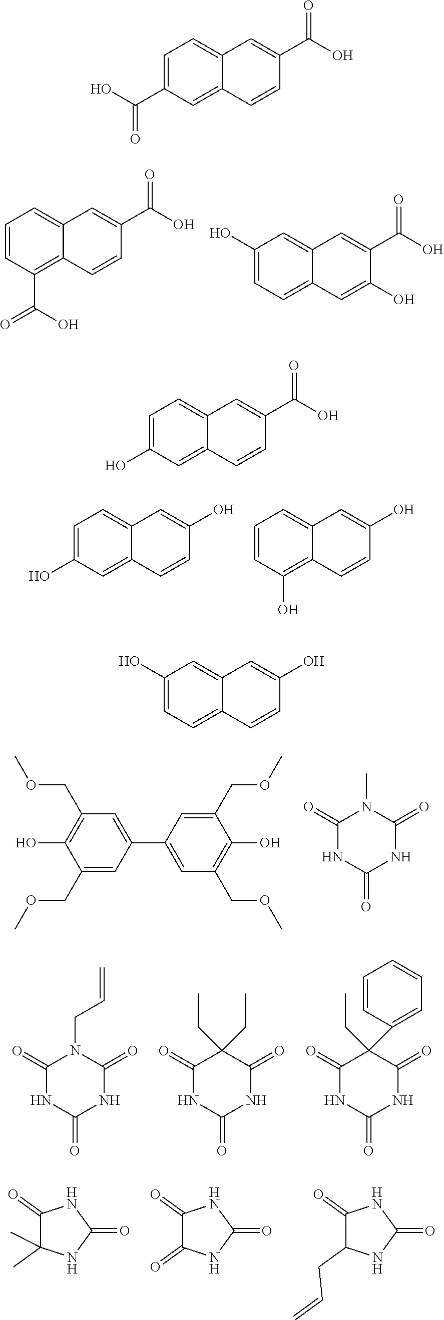

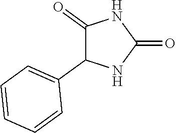 [SMILES: O=C1NC(=O)C(c2ccccc2)N1]

The compound (B) may contain a heterocyclic structure or an aromatic ring structure having 6 to 40 carbon atoms.

Examples of the heterocyclic structure include furan, thiophene, pyrrole, imidazole, pyran, pyridine, pyrimidine, pyrazine, pyrrolidine, piperidine, piperazine, morpholine, indole, purine, quinoline, isoquinoline, quinuclidine, chromene, thianthrene, phenothiazine, phenoxazine, xanthene, acridine, phenazine, carbazole, triazinone, triazinedione, and triazinetrione.

The heterocyclic structure may be a structure derived from barbituric acid.

The aromatic ring structure having 6 to 40 carbon atoms is as given above.

The compound (B) may be represented by the following formula (101):

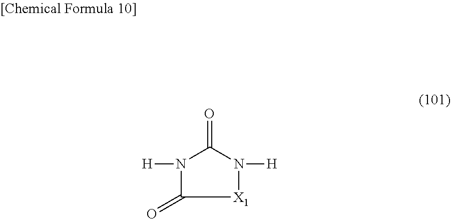

(in the formula (101), X¹ is represented by the formula (2), formula (3), formula (4), or formula (0) below:

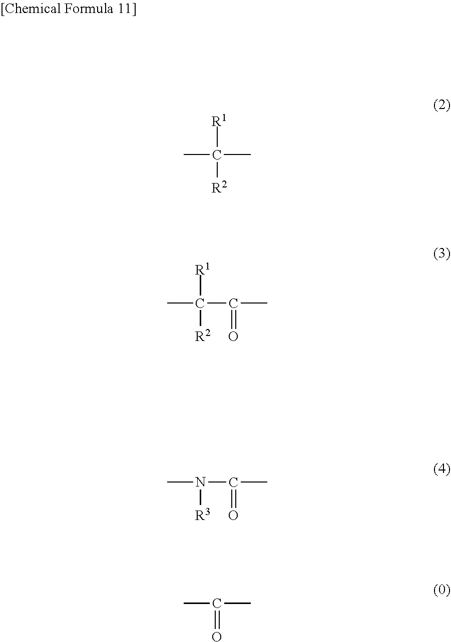

(in the formulae (2), (3), (4) and (0), R¹ and R² each independently represent a hydrogen atom, a halogen atom, an alkyl group having 1 to 10 carbon atoms, an alkenyl group having 2 to 10 carbon atoms, a benzyl group, or a phenyl group, and the alkyl group having 1 to 10 carbon atoms, the alkenyl group having 2 to 10 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 10 carbon atoms, and R¹ and R₂ may be bonded to each other to form a ring having 3 to 10 carbon atoms; R₃ represent a halogen atom, an alkyl group having 1 to 10 carbon atoms, an alkenyl group having 2 to 10 carbon atoms, a benzyl group, or a phenyl group, and the phenyl group may be substituted with a group selected from the group consisting of an alkyl group having 1 to 10 carbon atoms, a halogen atom, an alkoxy group having 1 to 10 carbon atoms, a nitro group, a cyano group, a hydroxy group, and an alkylthio group having 1 to 10 carbon atoms).

Examples of the halogen atom include fluorine, chlorine, bromine, and iodine atoms.

Examples of the alkylthio group having 1 to 10 carbon atoms include methylthio, ethylthio, propylthio, butylthio, pentylthio, hexylthio, heptylthio, octylthio, nonylthio, and decanylthio groups.

Examples of the ring having 3 to 10 carbon atoms include cyclopropane, cyclobutane, cyclopentane, cyclopentadiene, cyclohexane, cycloheptane, cyclooctane, cyclononane, and cyclodecane. The meaning of the other terms is as given above.

A terminal of the reaction product may contain a structure represented by the following formula (102):

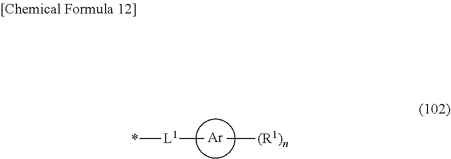

(in the formula (102), Ar represents an optionally substituted aromatic ring having 6 to 40 carbon atoms; L¹ represents an ester bond, an ether bond, or an optionally substituted alkenylene group having 2 to 10 carbon atoms; n quantity of R¹ independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a bonding site to the reaction product). The meaning of each term is as given above.

The structure represented by the formula (1-2) may be derived from cinnamic acid or salicylic acid that may be substituted with a halogen atom.

Examples of the compound that can be bonded to the terminal of the reaction product for inducing the structure represented by the formula (1-2) include compounds represented by the following formulas:

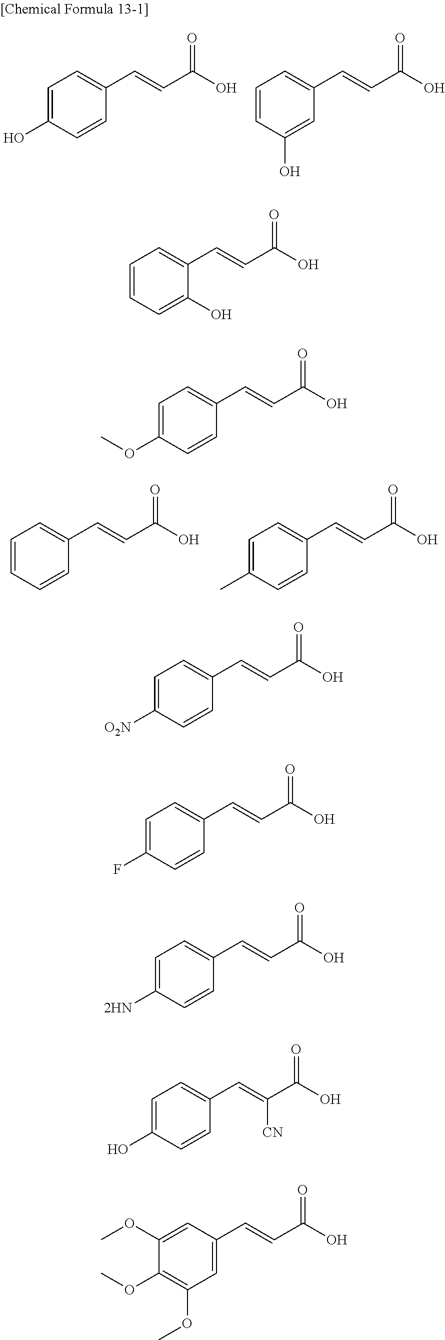

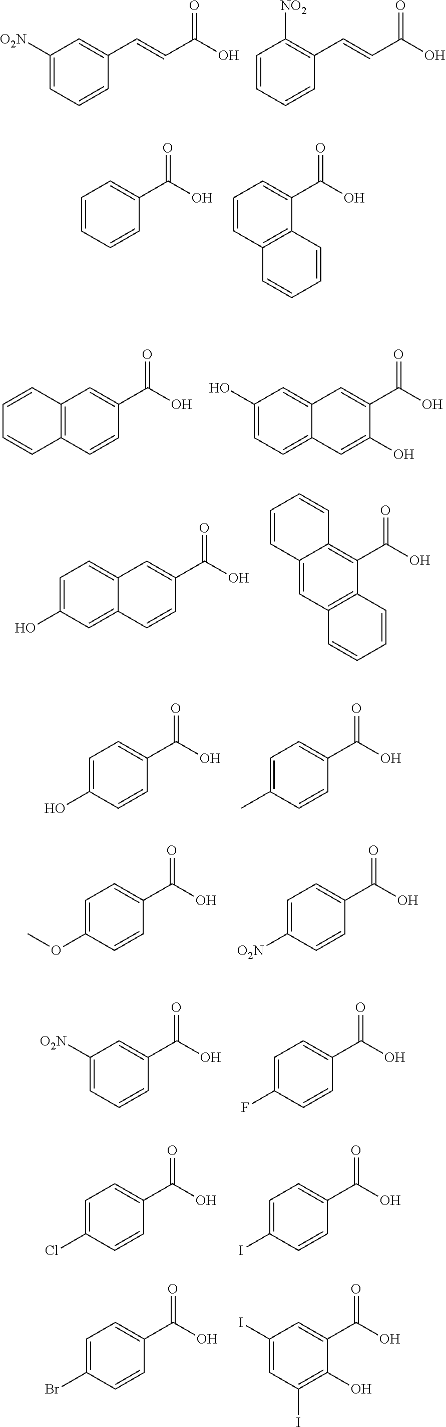

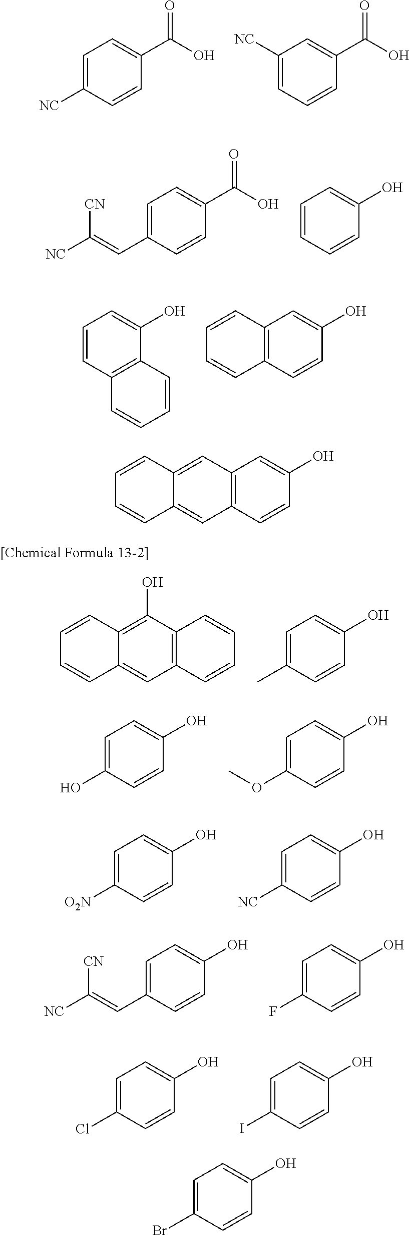

The terminal of the reaction product may have an aliphatic ring structure, in which a carbon-carbon bond may be interrupted by a heteroatom and the ring may be substituted with a substituent, as disclosed in WO 2020/226141.

The aliphatic ring may be a monocyclic or polycyclic aliphatic ring having 3 to 10 carbon atoms.

The polycyclic aliphatic ring may be a bicyclo ring or a tricyclo ring.

The aliphatic ring may have at least one unsaturated bond.

The substituent of the aliphatic ring may be selected from hydroxy groups, linear or branched alkyl groups having 1 to 10 carbon atoms, alkoxy groups having 1 to 20 carbon atoms, acyloxy groups having 1 to 10 carbon atoms, and carboxy groups.

Specific examples of the compound for inducing an aliphatic ring structure, in which a carbon-carbon bond may be interrupted by a heteroatom and the ring may be substituted with a substituent, to the end of the reaction product include compounds having the structures below.

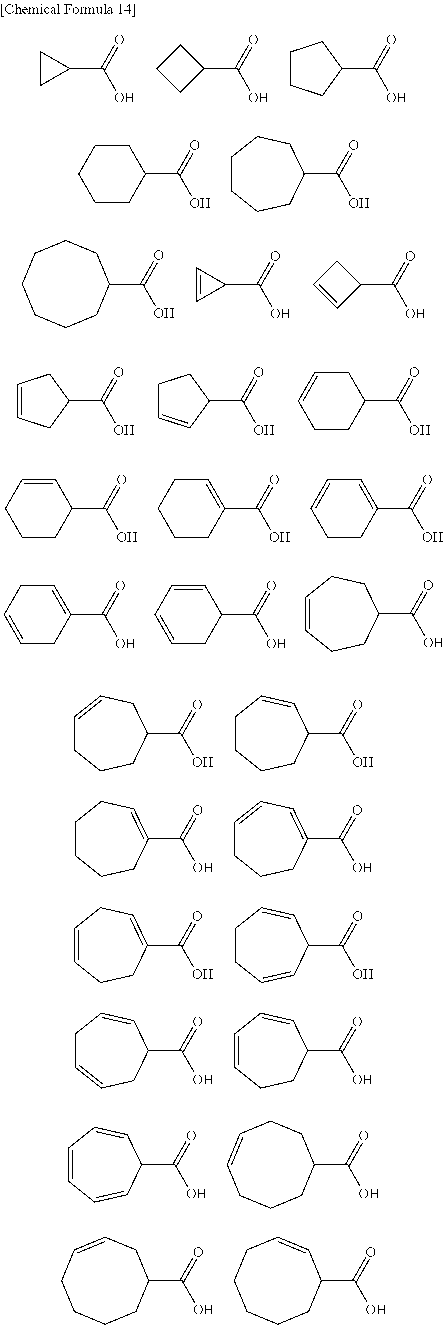

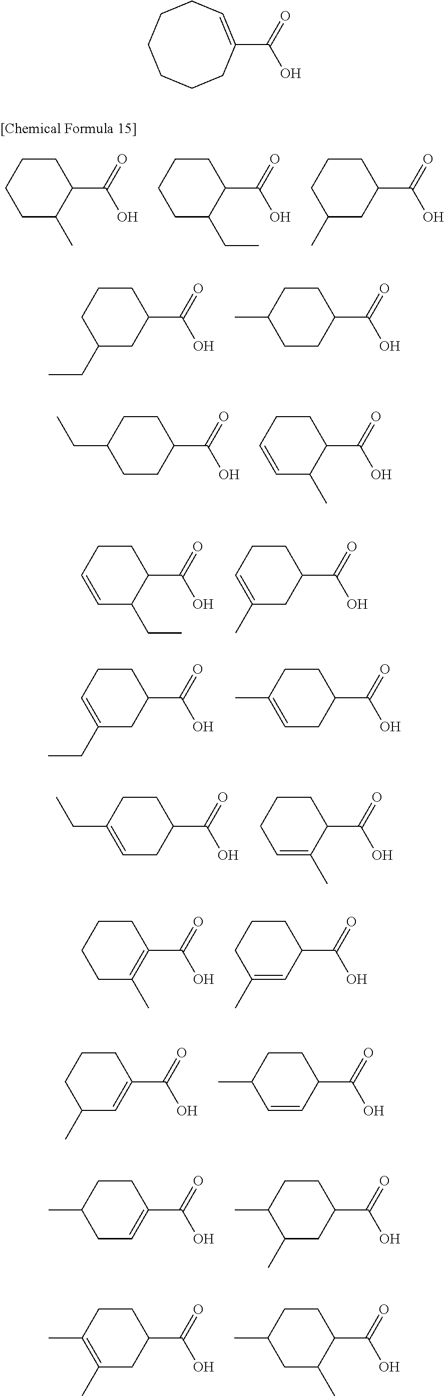

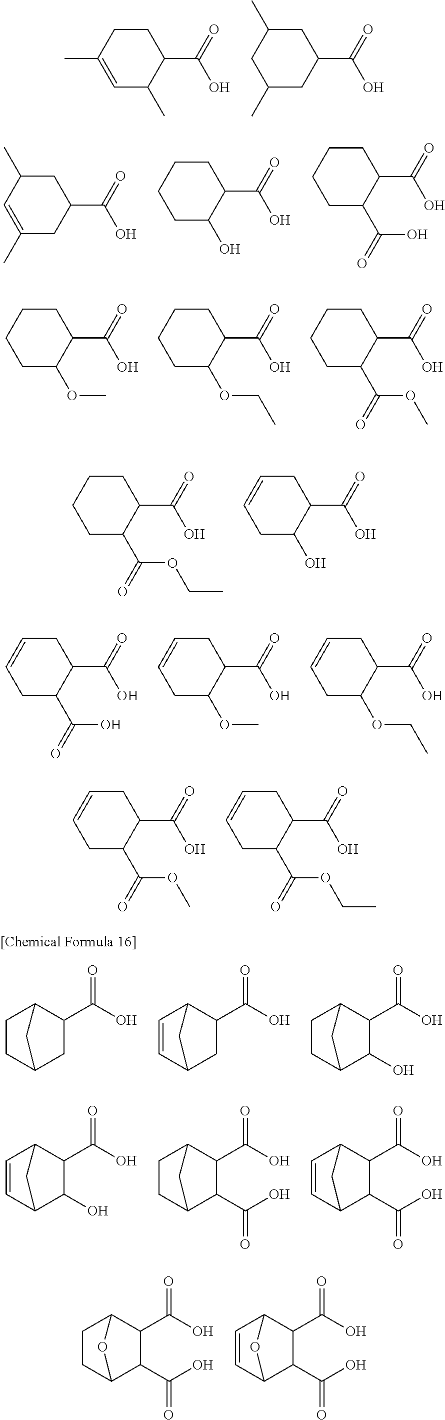

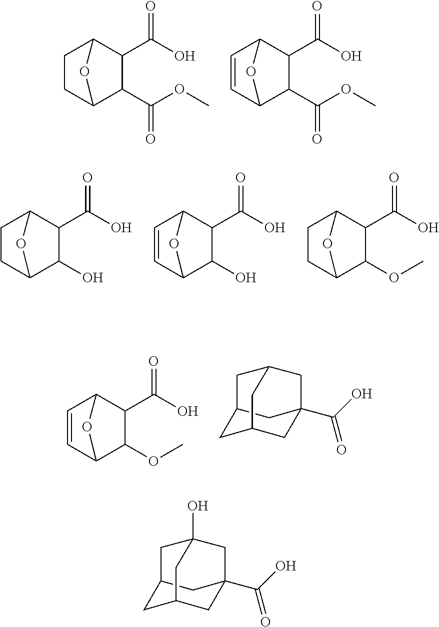

In addition, the terminal of the reaction product may have a structure disclosed in WO 2012/124597 and represented by the following formula (1):

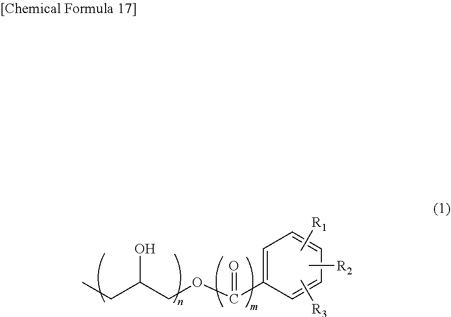

(wherein R¹, R², and R³ each independently represent a hydrogen atom, a linear or branched hydrocarbon group having 1 to 13 carbon atoms, or a hydroxy group, at least one of R¹, R², and R³ is the hydrocarbon group; m and n each independently represent 0 or 1; provided that the main chain of the polymer is bonded to a methylene group when n represents 1, and it is bonded to a group represented by —O— when n represents 0).

In addition, the terminal of the reaction product may have a structure disclosed in WO 2013/168610 and represented by the following formula (1a), (1b), or (2):

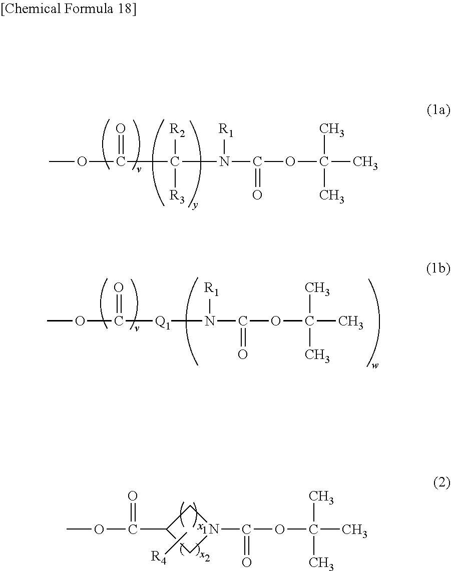

(wherein R₁ represents a hydrogen atom or a methyl group; R₂ and R₃ each independently represent a hydrogen atom, a linear or branched hydrocarbon group having 1 to 6 carbon atoms, an alicyclic hydrocarbon group, a phenyl group, a benzyl group, a benzyloxy group, a benzylthio group, an imidazole group, or an indole group, wherein the hydrocarbon group, the alicyclic hydrocarbon group, the phenyl group, the benzyl group, the benzyloxy group, the benzylthio group, the imidazole group, or the indole group may have at least one hydroxy group or methylthio group as a substituent; R₄ represents a hydrogen atom or a hydroxy group; Q₁ represents an arylene group; v represents 0 or 1; y represents an integer of 1 to 4; w represents an integer of 1 to 4; x₁ represents 0 or 1; and x₂ represents an integer of 1 to 5).

In addition, the terminal of the reaction product may have a structure disclosed in WO 2015/046149 and represented by the following formula (1):

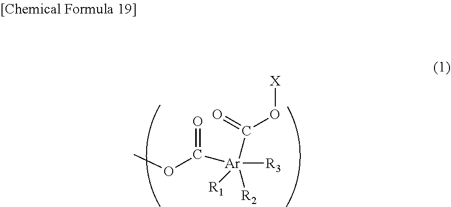

(wherein R₁, R₂, and R³ each independently represent a hydrogen atom, a linear or branched alkyl group having 1 to 13 carbon atoms, a halogeno group, or a hydroxy group, at least one of the R₁, R₂, and R₃ represents the alkyl group; Ar represents a benzene ring, a naphthalene ring, or an anthracene ring; the two carbonyl groups each bond to two adjacent carbon atoms of the ring represented by Ar; and X represents a linear or branched alkyl group having 1 to 6 carbon atoms which may have an alkoxy group having 1 to 3 carbon atoms as a substituent).

The terminal of the reaction product may have a structure represented by the following formula (1) or formula (2) disclosed in WO 2015/163195 at the terminal of the polymer chain:

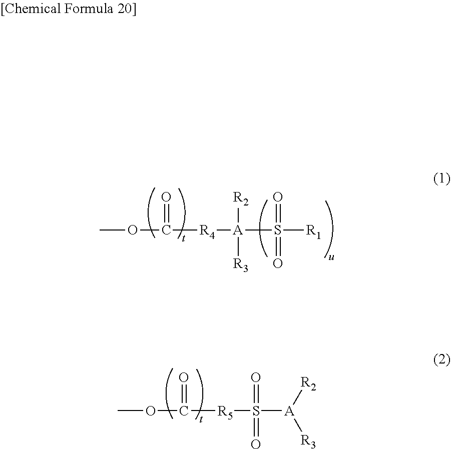

(wherein R₁ represents an optionally substituted alkyl group having 1 to 6 carbon atoms, a phenyl group, a pyridyl group, a halogeno group or a hydroxy group; R₂ represents a hydrogen atom, an alkyl group having 1 to 6 carbon atoms, a hydroxy group, a halogeno group or an ester group represented by —C(═O)O—X, X represents an optionally substituted alkyl group having 1 to 6 carbon atoms; R₃ represents a hydrogen atom, an alkyl group having 1 to 6 carbon atoms, a hydroxy group or a halogeno group; R₄ represents a direct bond or a divalent organic group having 1 to 8 carbon atoms; R₅ represents a divalent organic group having 1 to 8 carbon atoms; A represents an aromatic ring or an aromatic heterocyclic ring; t represents 0 or 1; and u represents 1 or 2).

The terminal of the reaction product may have a structure disclosed in WO 2020/071361 and represented by the following formula (1) or (2):

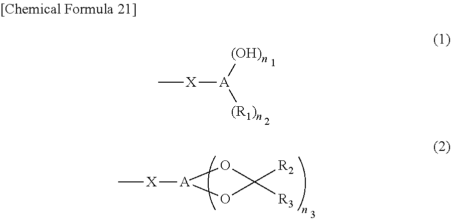

(in the above formulas (1) and (2), X is a divalent organic group; A is an aryl group having 6 to 40 carbon atoms; R₁ is a halogen atom, an alkyl group having 1 to 10 carbon atoms, or an alkoxy group having 1 to 10 carbon atoms; R₂ and R₃ are each independently a hydrogen atom, a halogen atom, an optionally substituted alkyl group having 1 to 10 carbon atoms, or an optionally substituted aryl group having 6 to 40 carbon atoms; n1 and n3 are each independently an integer of 1 to 12; and n2 is an integer of 0 to 11).

The entire disclosures of WO 2020/226141, WO 2012/124597, WO 2013/168610, WO 2015/046149, WO 2015/163195, and WO 2020/071361 are incorporated herein by reference.

The lower limit of the weight average molecular weight of the reaction product (polymer) measured by gel permeation chromatography as described in Examples, is, for example, 1,000 or 2,000, for example; and the upper limit of the weight average molecular weight of the reaction product is 30,000, 20,000, or 10,000, for example.

The resist underlayer film-forming composition of the present invention may be an EUV resist underlayer film-forming composition used for an extreme ultraviolet (EUV) exposure process.

### <Solvent>

The solvent to be used in the resist underlayer film-forming composition of the present invention is not particularly limited as long as it is a solvent capable of uniformly dissolving solid components such as the polymer at normal temperature, but is preferably an organic solvent generally used for chemical solutions for semiconductor lithography processes. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-ethoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanisol, methoxy cyclopentane, anisole, γ-butyrolactone, N-methylpyrrolidone, N,N-dimethylformamide, and N,N-dimethylacetamide. These solvents may be used each alone or in combination of two or more thereof.

Of these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Acid Generator>

The acid generator contained as an optional component in the resist underlayer film-forming composition of the present invention may be either a thermal acid generator or a photoacid generator, but is preferably a thermal acid generator. Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include onium salt compounds, sulfonimide compounds, and disulfonyldiazomethane compounds.

Examples of the onium salt compound include iodonium salt compounds such as diphenyliodonium bexafluorophosphate, diphenyliodonium trifluoromethanesulfonate, diphenyliodonium nonafluoronormalbutanesulfonate, diphenyliodonium perfluoronormaloctanesulfonate, diphenyliodonium camphor sulfonate, bis(4-tert-butylphenyl)iodonium camphor sulfonate, and bis(4-tert-butylphenyl)iodonium, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generator may be used each alone or in combination of two or more thereof.

When the acid generator is used, the content ratio of the acid generator is, for example, within the range of from 0.1% by mass to 50% by mass, and preferably from 1% by mass to 30% by mass relative to the crosslinking agent described below.

### <Crosslinking Agent>

Examples of the crosslinking agent included as an optional component in the resist underlayer film-forming composition of the present invention include hexamethoxymethylmelamine, tetramethoxymethylbenzoguanamine, 1,3,4,6-tetrakis(methoxymethyl)glycoluril (tetramethoxymethylglycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

In addition, the crosslinking agent of the present application may be a nitrogen-containing compound represented by the following formula (1d) having 2 to 6 substituents bonded to a nitrogen atom per molecule, which is described in WO 2017/187969 A:

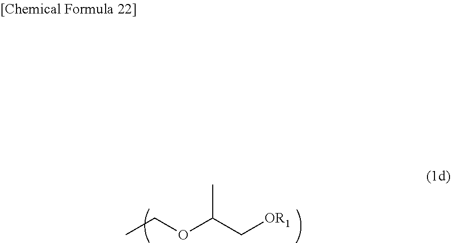

(in the formula (1d), R₁ represents a methyl group or an ethyl group).

The nitrogen-containing compound represented by the formula (1d) having 2 to 6 substituents per molecule may be a glycoluril derivative represented by the following formula (1E):

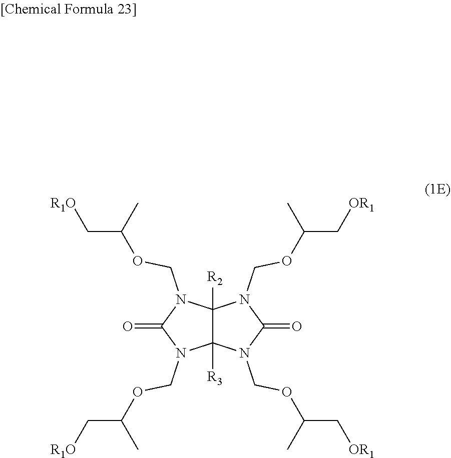

(in the formula (1E), four R₁s each independently represent a methyl group or an ethyl group; and R₂ and R₃ each independently represent a hydrogen atom, an alkyl group having 1 to 4 carbon atoms, or a phenyl group).

Examples of the glycoluril derivative represented by the formula (1E) include compounds represented by the following formulas (1E-1) through (1E-6).

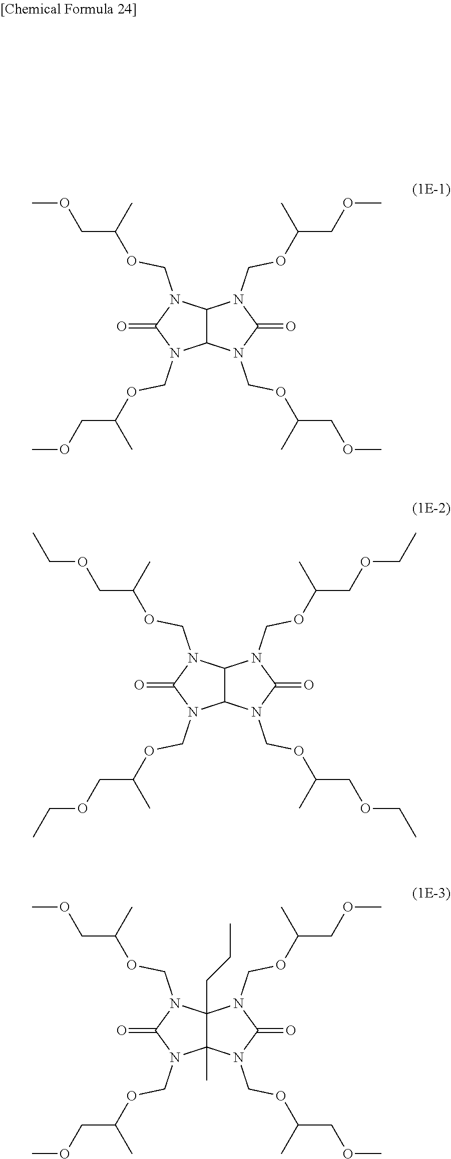

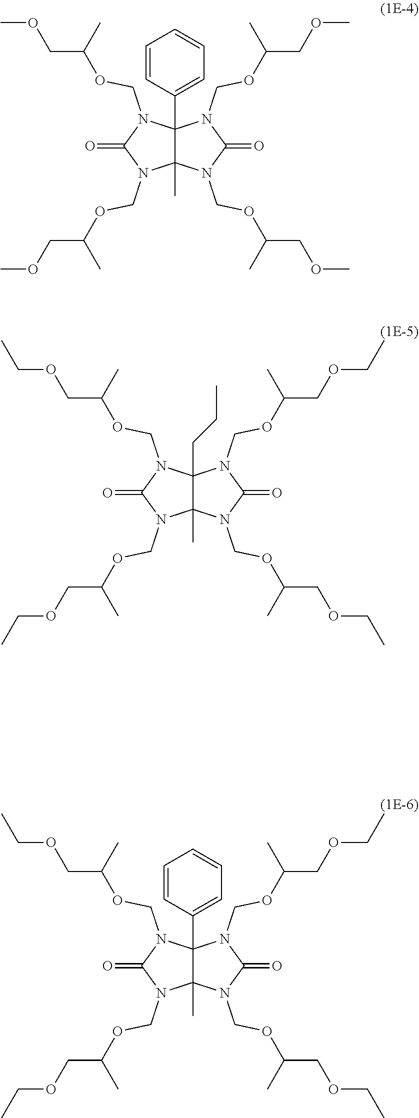

The nitrogen-containing compound represented by the formula (1d) having 2 to 6 substituents per molecule is obtained by reacting a nitrogen-containing compound represented by the following formula (2d) having, per molecule, 2 to 6 substituents that bond to a nitrogen atom, with at least one compound represented by the following formula (3d):

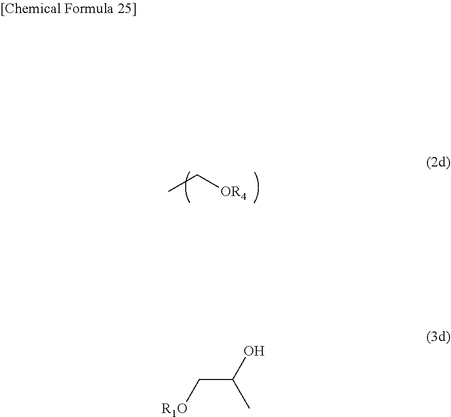

(in the formulas (2d) and (3d), R₁ represents a methyl group or an ethyl group; and R₄ represents an alkyl group having 1 to 4 carbon atoms).

The glycoluril derivative represented by the formula (1E) is obtained by reacting a glycoluril derivative represented by the following formula (2E) with at least one compound represented by the formula (3d).

The nitrogen-containing compound represented by the formula (2d) having 2 to 6 substituents per molecule is, for example, a glycoluril derivative represented by the following formula (2E):

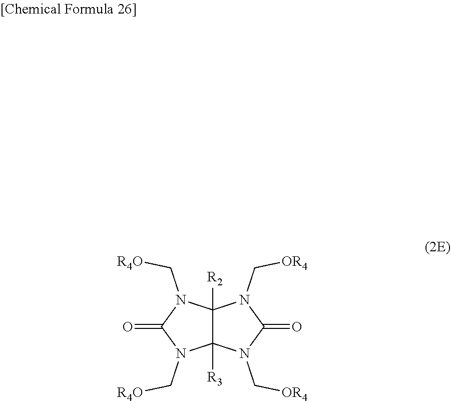

(in the formula (2E), R₂ and R₃ each independently represent a hydrogen atom, an alkyl group having 1 to 4 carbon atoms, or a phenyl group; and R₄ each independently represents an alkyl group having 1 to 4 carbon atoms).

Examples of the glycoluril derivative represented by the formula (2E) include compounds represented by the following formulas (2E-1) to (2E-4). Furthermore, examples of the glycoluril derivative represented by the formula (3d) include compounds represented by the following formulas (3d-1) to (3d-2).

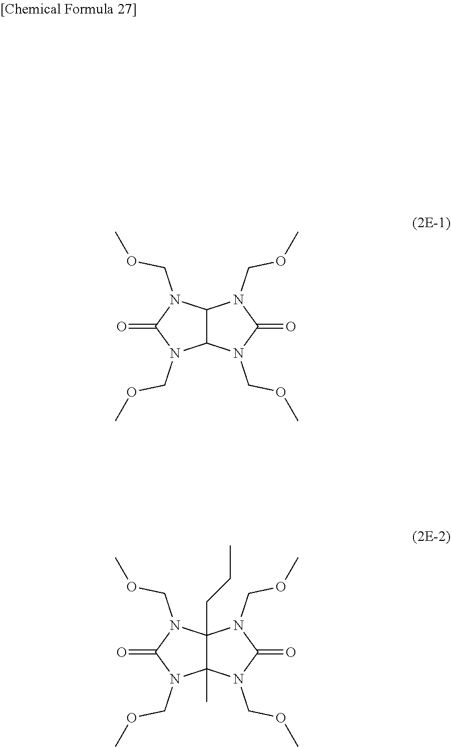

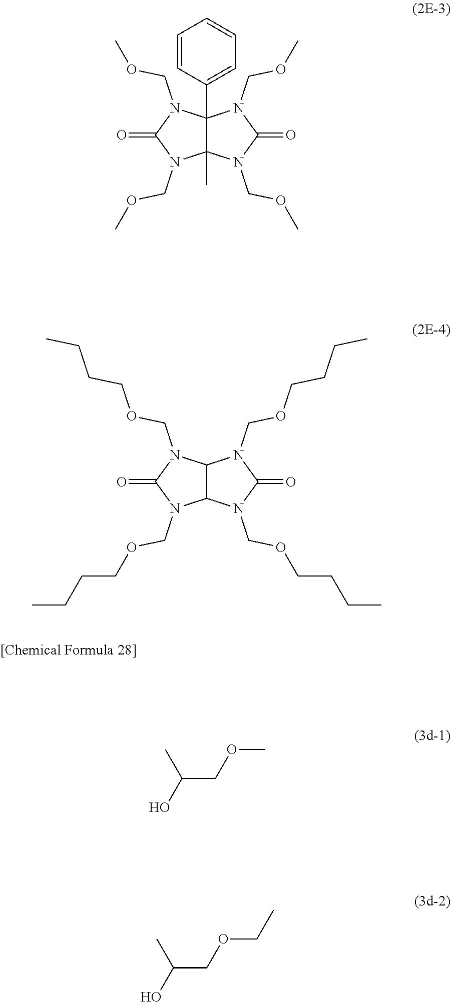

With regard to the details of the nitrogen-containing compound represented by the following formula (1d) having 2 to 6 substituents that bond to the nitrogen atom per molecule, the entire disclosure of WO 2017/187969 is incorporated in the present application.

The crosslinking agent may be a crosslinkable compound represented by the following formula (G-1) or (G-2) disclosed in WO 2014/208542 A:

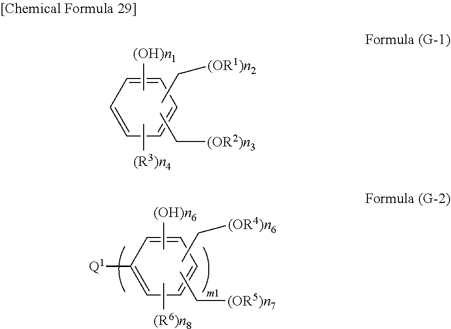

(wherein Q¹ represents a single bond or an m1-valent organic group; R¹ and R⁴ each represent an alkyl group having 2 to 10 carbon atoms or an alkyl group having 2 to 10 carbon atoms having an alkoxy group having 1 to 10 carbon atoms; R² and R⁵ each represent a hydrogen atom or a methyl group; and R³ and R⁶ each represent an alkyl group having 1 to 10 carbon atoms or an aryl group having 6 to 40 carbon atoms; n1 represents an integer that meets 1≤n1≤3; n2 represents an integer that meets 2≤n2≤5; n3 represents an integer that meets 0≤n3≤3; n4 represents an integer that meets 0≤n4≤3, and 3≤(n1+n2+n3+n4)≤6; n5 represents an integer that meets 1≤n5≤3; n6 represents an integer that meets 1≤n6≤4; n7 represents an integer that meets 0≤n7≤3; n8 represents an integer that meets 0≤n8≤3, and 2≤(n5+n6+n7+n8)≤5; m1 represents an integer of 2 to 10).

The crosslinkable compound represented by the formula (G-1) or (G-2) may be obtained by reaction of a compound represented by the following formula (G-3) or (G-4) with a hydroxy group-containing ether compound or an alcohol having 2 to 10 carbon atoms:

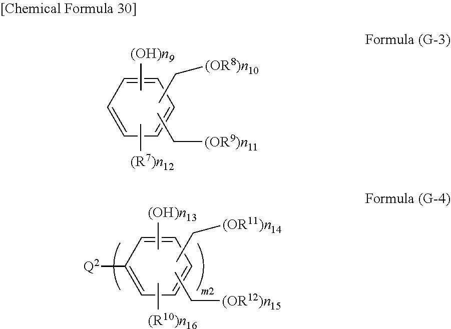

(wherein Q² represents a single bond or an m2-valent organic group; R⁸, R⁹, R¹¹, and R¹² each represent a hydrogen atom or a methyl group; and R⁷ and R¹⁰ each represent an alkyl group having 1 to 10 carbon atoms or an aryl group having 6 to 40 carbon atoms;
n9 represents an integer that meets 1≤n9≤3; n10 represents an integer that meets 2≤n10≤5; n11 represents an integer that meets 0≤n11≤3; n12 represents an integer that meets 0≤n12≤3; and 3≤(n9+n10+n11+n12)≤6;
n13 represents an integer that meets 1≤n13≤3; n14 represents an integer that meets 1≤n14≤4; n15 represents an integer that meets 0≤n15≤3; n16 represents an integer that meets 0≤n16≤3, and 2≤(n13+n14+n15+n16)≤5;
m2 represents an integer of 2 to 10).

Examples of the compounds represented by the formula (G-1) and the formula (G-2) are listed below:

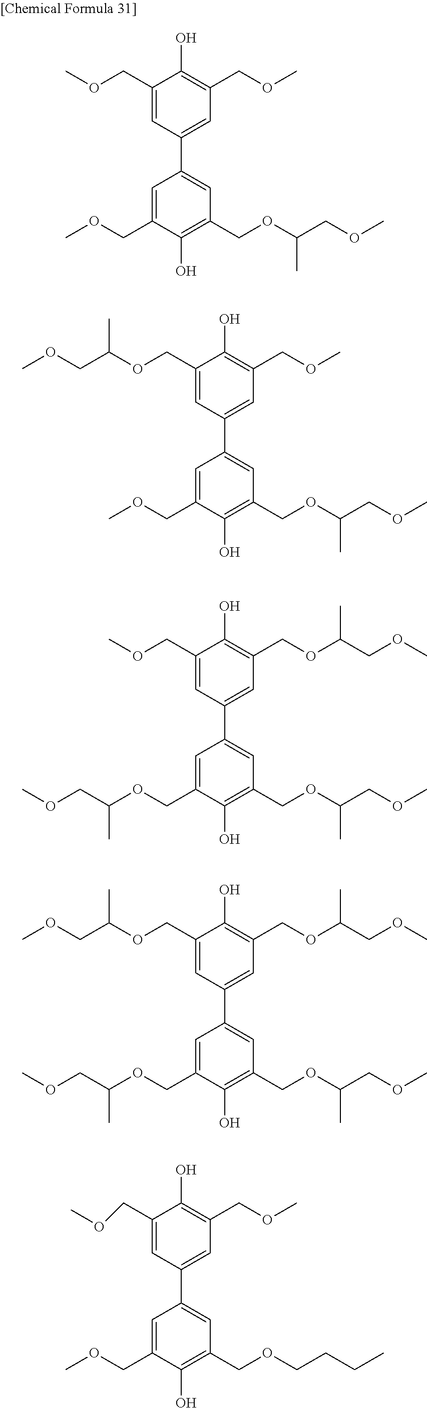

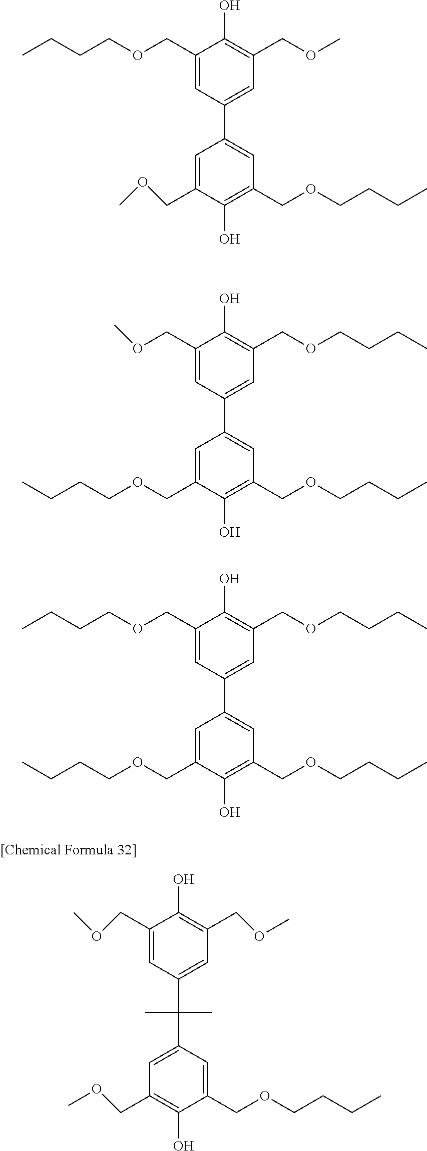

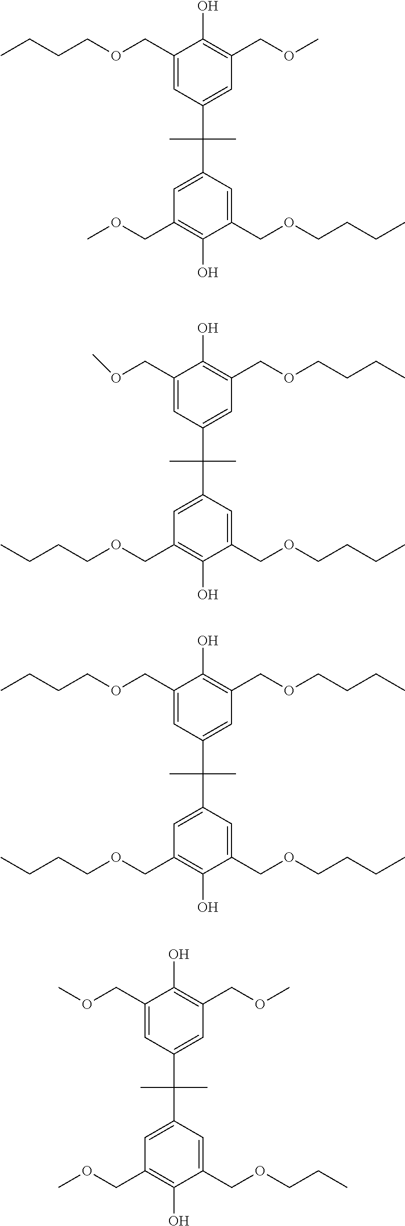

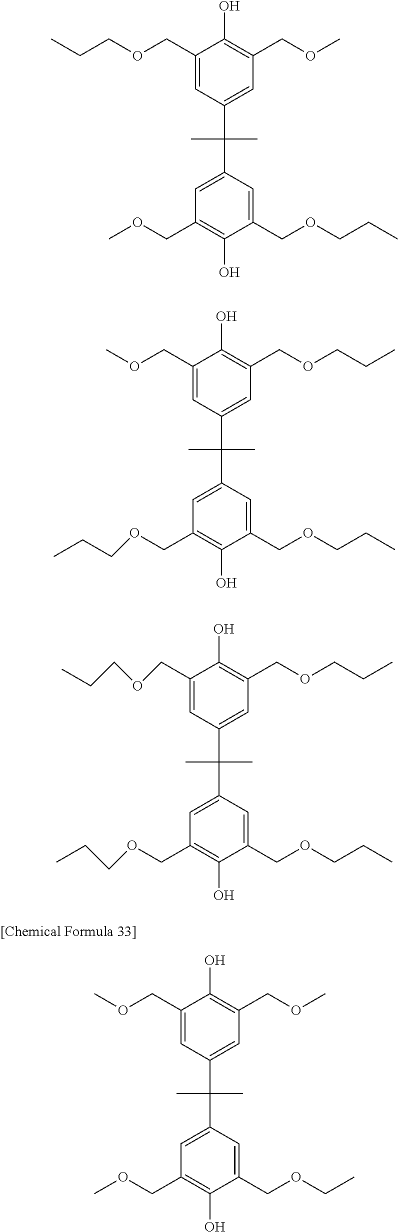

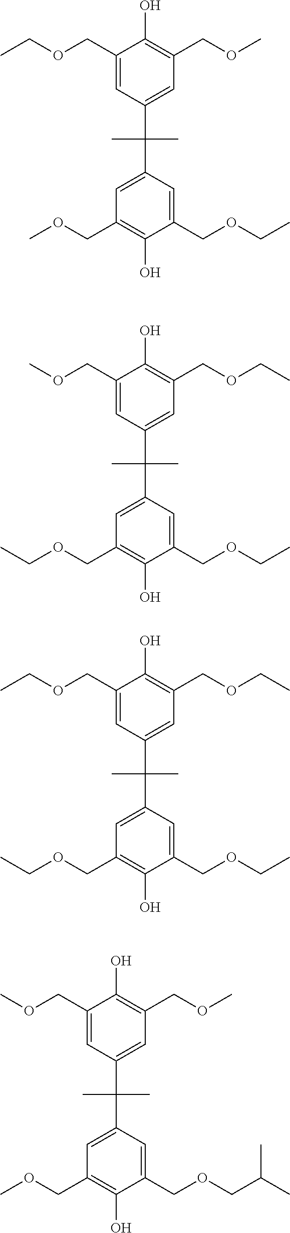

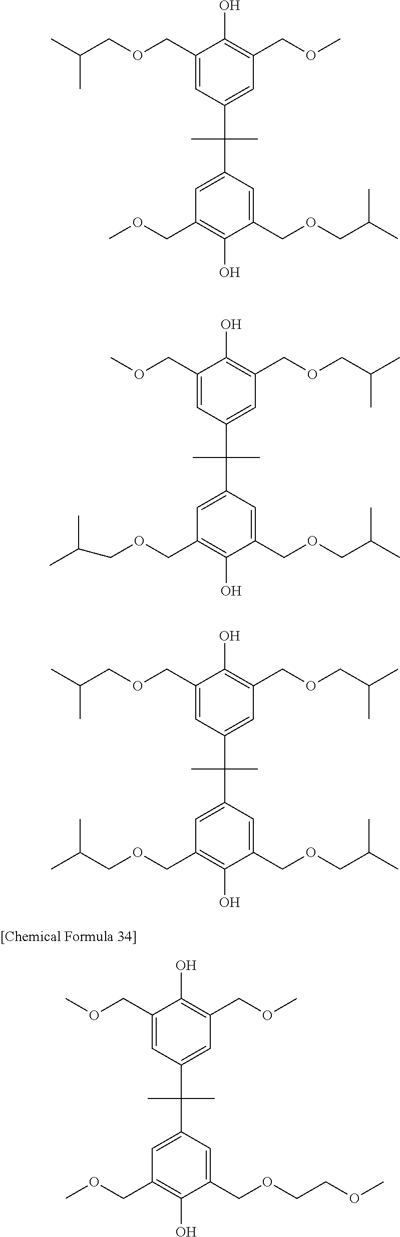

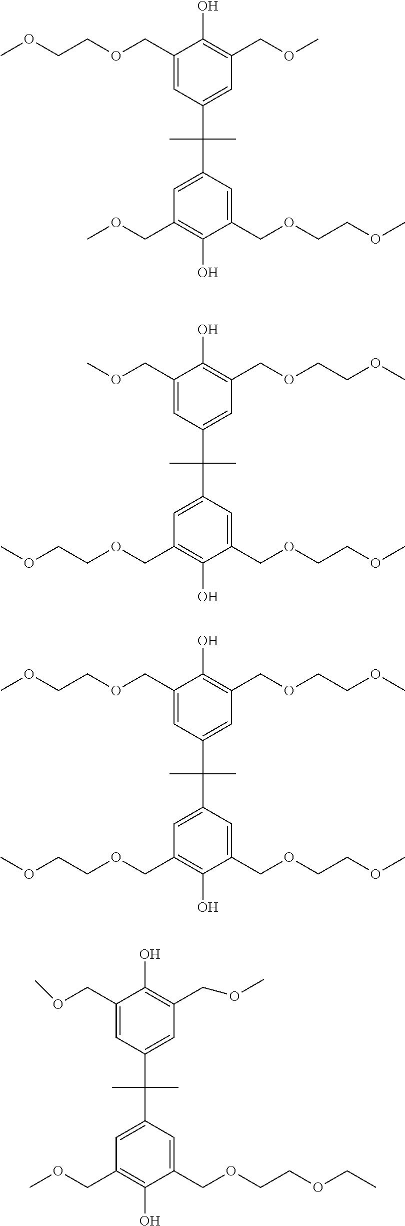

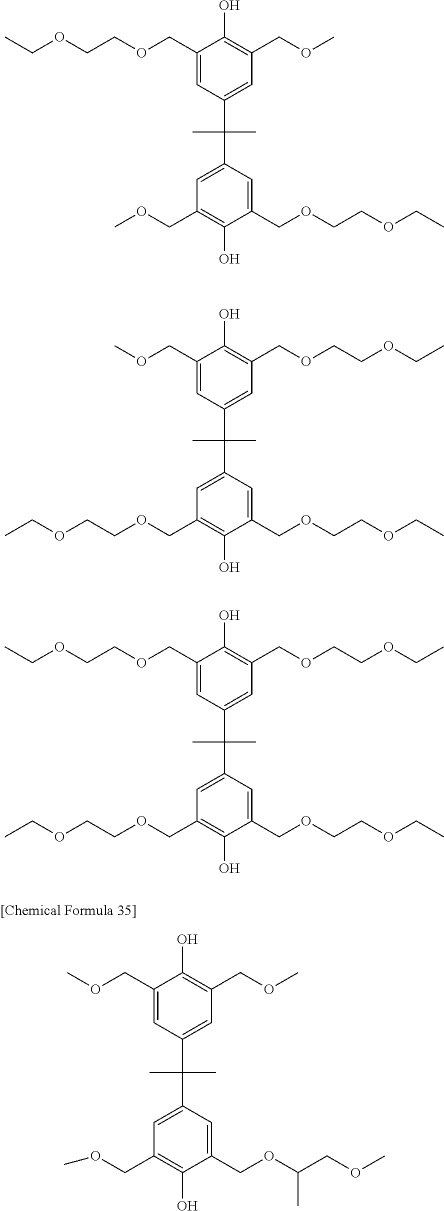

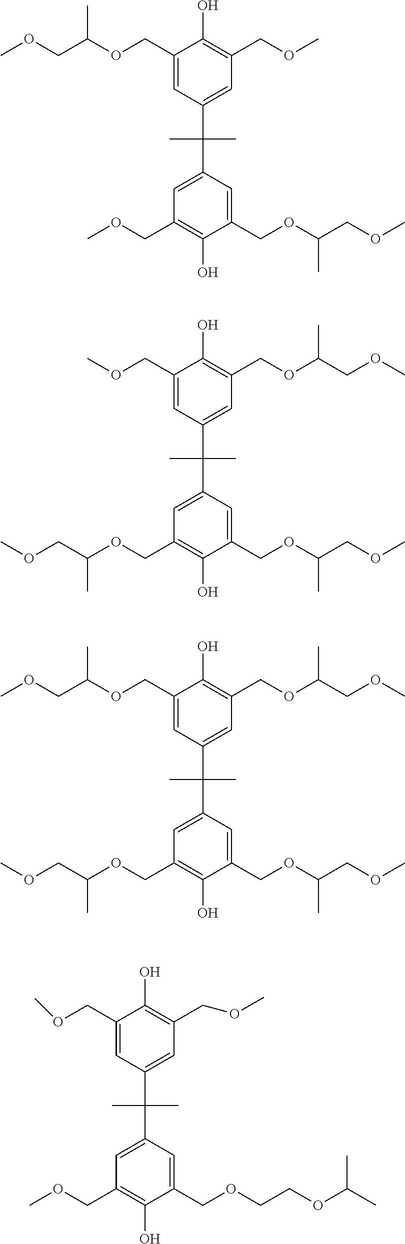

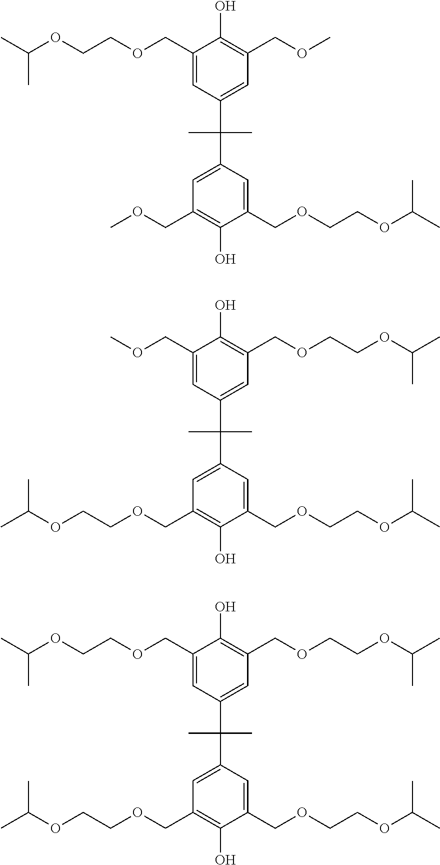

Examples of the compounds represented by the formula (G-3) and the formula (G-4) are listed below:

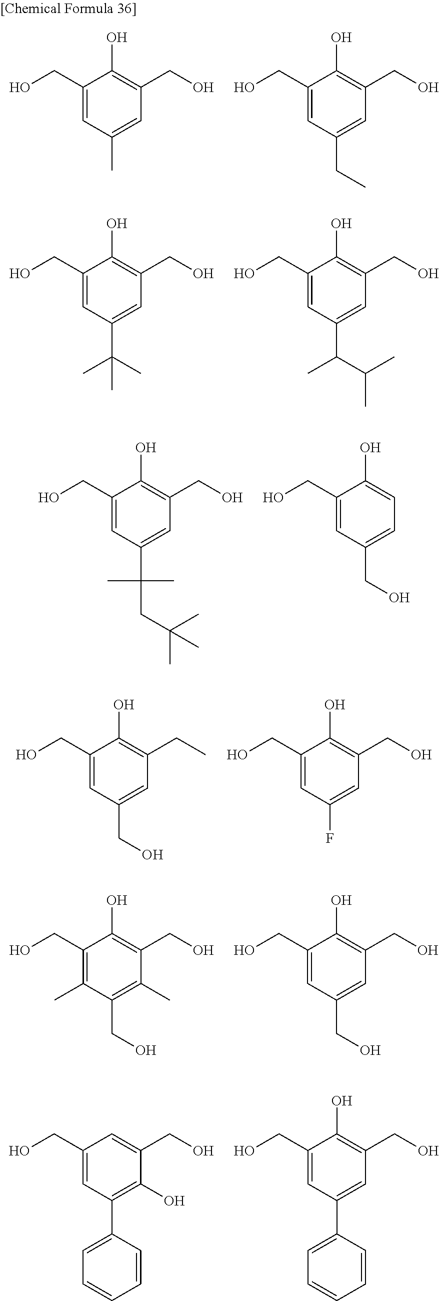

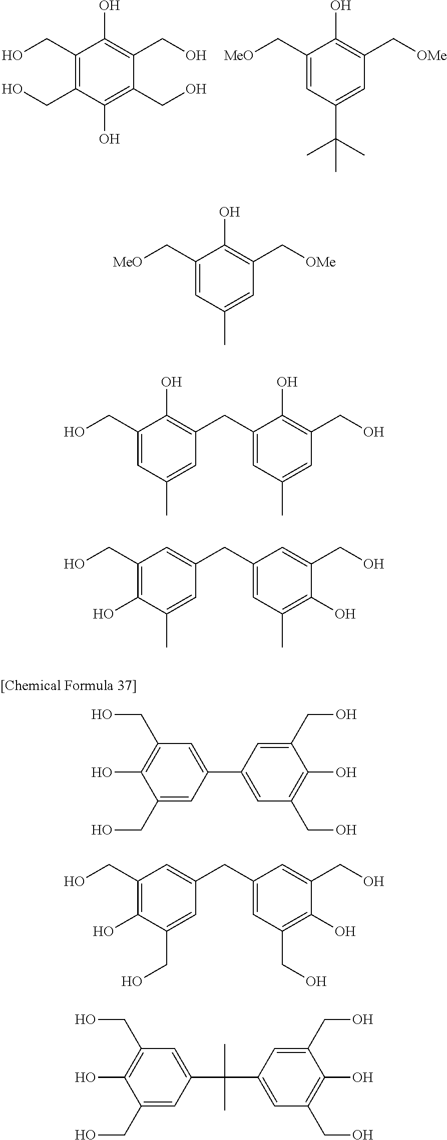

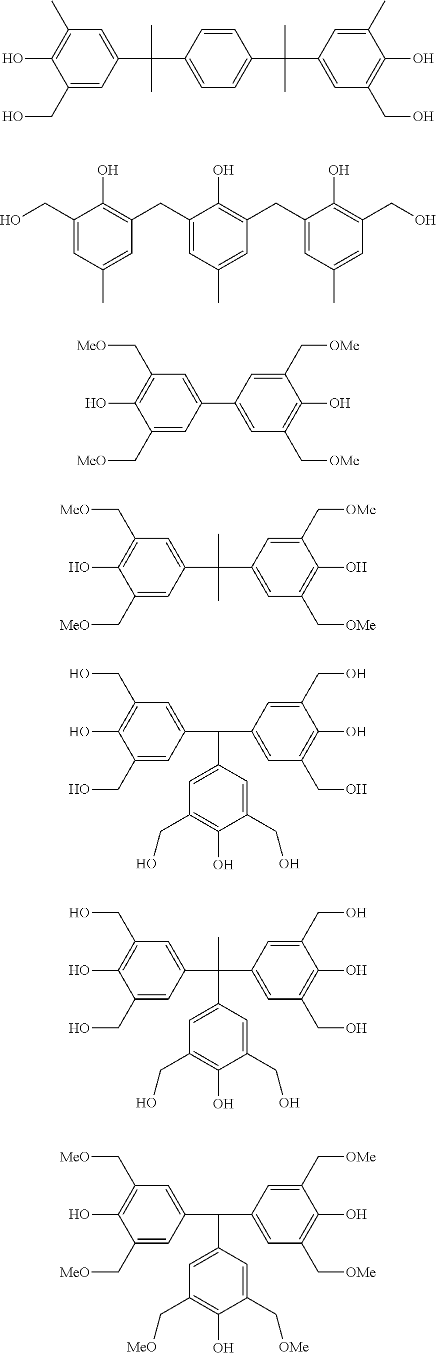

wherein Me represents a methyl group.

The entire disclosure of WO 2014/208542 is incorporated herein by reference.

When the crosslinking agent is used, the content ratio of the crosslinking agent is, for example, within the range of from 1% by mass to 50% by mass, and preferably from 5% by mass to 30% by mass relative to the reaction product.

### <Other Components>

The resist underlayer film-forming composition of the present invention may include a surfactant to prevent pinholes and striations, and to further improve the application properties to uneven surfaces. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octyl phenol ether and polyoxyethylene nonyl phenol ethers; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorosurfactants such as F-Top EF301, EF303, and EF352 (trade names, manufactured by Tohchem Products Co., Ltd.), Megaface F171, F173, and R-30 (trade names, manufactured by Dainippon Ink and Chemicals, Inc.), Fluorad FC430 and FC431 (trade names, manufactured by Sumitomo 3M Limited.), and Asahi Guard AG710, Surflon S-382, SC101, SC102, SC103, SC104, SC105, and SC106 (trade names, manufactured by Asahi Glass Co., Ltd); and organosiloxane polymer KP341 (manufactured by Shin-Etsu Chemical Co., Ltd.). The blending amount of these surfactants is usually 2.0% by mass or less, preferably 1.0% by mass or less of the total solid content of the resist underlayer film-forming composition of the present invention. These surfactants may be added each alone or in combination of two or more thereof.

The solid content in the resist underlayer film-forming composition of the present invention, that is, the component excluding the aforementioned solvent, is, for example, within the range of from 0.01% by mass to 10% by mass.

### <Resist Underlayer Film>

The resist underlayer film according to the present invention may be produced by applying the above-described resist underlayer film-forming composition onto a semiconductor substrate and baking the applied composition.

Examples of the semiconductor substrate to which the resist underlayer film-forming composition of the present invention is applied include silicon wafers, germanium wafers, and compound semiconductor wafers such as gallium arsenide, indium phosphide, gallium nitride, indium nitride, and aluminum nitride.

When a semiconductor substrate having an inorganic film formed on its surface is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The resist underlayer film-forming composition of the present invention is applied onto such a semiconductor substrate by an appropriate application method such as a spinner or a coater. Thereafter, baking is performed using a heating means such as a hot plate to form a resist underlayer film. The baking conditions are appropriately selected from a baking temperature of from 100° C. to 400° C. and a baking time of from 0.3 minutes to 60 minutes. Preferably, the baking temperature is from 120° C. to 350° C. and the baking time is from 0.5 minutes to 30 minutes, and more preferably, the baking temperature is from 150° C. to 300° C. and the baking time is from 0.8 minutes to 10 minutes.

The film thickness of the resist underlayer film to be formed is, for example, within the range of from 0.001 μm (1 nm) to 10 μm, from 0.002 μm (2 nm) to 1 μm, from 0.005 μm (5 nm) to 0.5 μm (500 nm), from 0.001 μm (1 nm) to 0.05 μm (50 nm), from 0.002 μm (2 nm) to 0.05 μm (50 nm), from 0.003 μm (3 nm) to 0.05 μm (50 nm), from 0.004 μm (4 nm) to 0.05 μm (50 nm), from 0.005 μm (5 nm) to 0.05 μm (50 nm), from 0.003 μm (3 nm) to 0.03 μm (30 nm), from 0.003 μm (3 nm) to 0.02 μm (20 nm), from 0.005 μm (5 nm) to 0.02 μm (20 nm), from 0.003 μm (3 nm) to 0.01 μm (10 nm), from 0.005 μm (5 nm) to 0.01 μm (10 nm), from 0.003 μm (3 nm) to 0.006 μm (6 nm), 0.004 μm (4 nm), and 0.005 μm (5 nm). When the temperature during baking is lower than the above range, crosslinking becomes insufficient. To the contrary, when the temperature during baking is higher than the above range, the resist underlayer film may be decomposed by heat.

### <Method for Producing Patterned Substrate, and Method for Producing Semiconductor Device>

A method for producing a patterned substrate comprises the following steps. It is usually produced by forming a photoresist layer on a resist underlayer film. The photoresist formed by coating followed by baking on a resist underlayer film by a known method is not particularly limited as long as it is sensitive to the light used for exposure. Both negative and positive photoresists may be used. Examples thereof include positive photoresists including a novolac resin and 1,2-naphthoquinone diazide sulfonate; chemically amplified photoresists including a binder having a group that is decomposed by acid to increase the alkali dissolution rate and a photoacid generator; chemically amplified photoresists including a low molecular weight compound that is decomposed by acid to increase the alkali dissolution rate of photoresist, an alkaline soluble binder, and a photoacid generator; and chemically amplified photoresists including a binder having a group that is decomposed by acid to increase the alkali dissolution rate, a low molecular weight compound that is decomposed by acid to increase the alkali dissolution rate of the photoresist, and a photoacid generator. Examples thereof include V146G (trade name) manufactured by JSR Corporation, APEX-E (trade name) manufactured by Shipley, PAR710 (trade name) manufactured by Sumitomo Chemical Co., Ltd., and AR2772 and SEPR430 (trade name) manufactured by Shin-Etsu Chemical Co., Ltd. Other examples include fluorinated polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Other examples include, but not limited to, the so-called resist compositions and metal-containing resist compositions, such as resist compositions, radiation-sensitive resin compositions, and high-resolution patterning compositions based on organometallic solutions disclosed in WO 2019/188595, WO 2019/187881, WO 2019/187803, WO 2019/167737, WO 2019/167725, WO 2019/187445, WO 2019/167419, WO 2019/123842, WO 2019/054282, WO 2019/058945, WO 2019/058890, WO 2019/039290, WO 2019/044259, WO 2019/044231, WO 2019/026549, WO 2018/193954, WO 2019/172054, WO 2019/021975, WO 2018/230334, WO 2018/194123, JP 2018-180525, WO 2018/190088, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482, JP 2016-29498 A, and JP 2011-253185 A.

Examples of the resist composition include the following compositions.

An active ray-sensitive or radiation-sensitive resin composition including: a resin A having a repeating unit having an acid-decomposable group in which a polar group is protected by a protecting group that is eliminated by an action of an acid, and a compound represented by general formula (21):

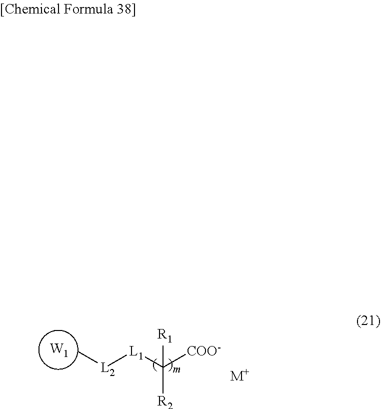

in the general formula (21), m represents an integer of 1 to 6;
R₁ and R₂ each independently represent a fluorine atom or a perfluoroalkyl group;
L₁ represents —O—, —S—, —COO—, —SO₂—, or —SO₃—;
L₂ represents a single bond or an optionally substituted alkylene group;
W¹ represents an optionally substituted cyclic organic group; and
M⁺ represents a cation.

A metal-containing film-forming composition for extreme ultraviolet ray or electron beam lithography, including: a solvent and a compound having a metal-oxygen covalent bond, wherein a metal element constituting the compound belongs to the third to seventh periods of Groups 3 to 15 of the periodic table.

A radiation-sensitive resin composition including: a polymer having a first structural unit represented by the following formula (31) and a second structural unit represented by the following formula (32) and containing an acid-dissociable group; and an acid generator:

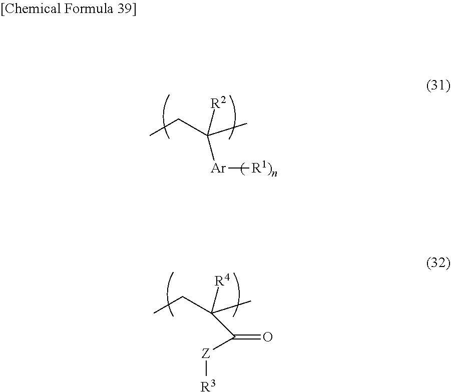

(in the formula (31), Ar is a group obtained by removing (n+1) hydrogen atoms from an arene having 6 to 20 carbon atoms; R¹ is a hydroxy group, a sulfanyl group, or a monovalent organic group having 1 to 20 carbon atoms; n is an integer of 0 to 11; when n is 2 or more, a plurality of R¹s are identical or different; R² is a hydrogen atom, a fluorine atom, a methyl group, or a trifluoromethyl group; in the formula (32), R³ is a monovalent group having 1 to 20 carbon atoms and containing the acid-dissociable group; Z is a single bond, an oxygen atom, or a sulfur atom; and R⁴ is a hydrogen atom, a fluorine atom, a methyl group, or a trifluoromethyl group).

A resist composition comprising: an acid generator and a resin (A1) containing a structural unit having a cyclic carbonate structure represented by formula (II), and a structural unit having an acid-unstable group:

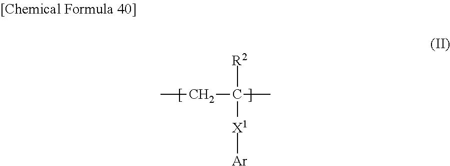

[in the formula (II), R⁴ represents an alkyl group having 1 to 6 carbon atoms which may have a halogen atom, a hydrogen atom or a halogen atom; X¹ represents a single bond, —CO—O—* or —CO—NR⁴—*; * represents a bond with —Ar; R⁴ represents a hydrogen atom or an alkyl group having 1 to 4 carbon atoms; and Ar represents an aromatic hydrocarbon group having 6 to 20 carbon atoms which may have one or more groups selected from the group consisting of a hydroxy group and a carboxyl group].

Examples of the resist film include the following.

A resist film including a base resin containing a repeating unit represented by the following formula (a1) and/or a repeating unit represented by the following formula (a2), and a repeating unit that generates an acid bonded to a polymer main chain by exposure.

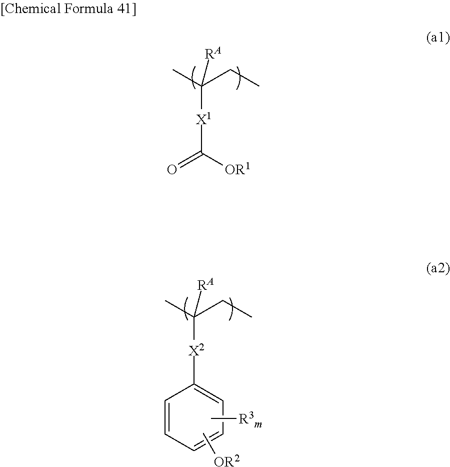

(in the formulas (a1) and (a2), R^{A} is each independently a hydrogen atom or a methyl group; R¹ and R² are each independently a tertiary alkyl group having 4 to 6 carbon atoms; R³ is each independently a fluorine atom or a methyl group; m is an integer of 0 to 4; X¹ is a single bond, a phenylene group, a naphthylene group, or a linking group having 1 to 12 carbon atoms containing at least one selected from an ester bond, a lactone ring, a phenylene group, and a naphthylene group; and X² is a single bond, an ester bond, or an amide bond).

Examples of the resist material include the following.

A resist material containing a polymer having a repeating unit represented by the following formula (b1) or (b2).

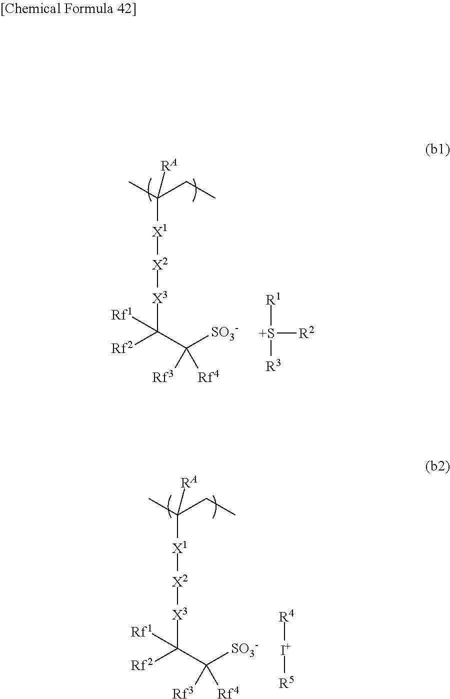

(in the formulas (b1) and (b2), R^{A} is a hydrogen atom or a methyl group; X¹ is a single bond or an ester group; X² is a linear, branched, or cyclic alkylene group having 1 to 12 carbon atoms or an arylene group having 6 to 10 carbon atoms, and a part of the methylene group constituting the alkylene group may be substituted with an ether group, an ester group, or a lactone ring-containing group, and at least one hydrogen atom contained in X² is substituted with a bromine atom; X³ is a single bond, an ether group, an ester group, or a linear, branched or cyclic alkylene group having 1 to 12 carbon atoms, and a part of the methylene group constituting the alkylene group may be substituted with an ether group or an ester group; Rf¹ to Rf⁴ are each independently a hydrogen atom, a fluorine atom, or a trifluoromethyl group, and at least one of them is a fluorine atom or a trifluoromethyl group. In addition, Rf¹ and Rf² may be combined to form a carbonyl group; R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, wherein some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and some of methylene groups constituting these groups may be substituted with an ether group, an ester group, a carbonyl group, a carbonate group, or a sulfonic acid ester group; and R′ and R² may be bonded to form a ring together with the sulfur atom to which they are bonded).

A resist material including a base resin including a polymer containing a repeating unit represented by the following formula (a):

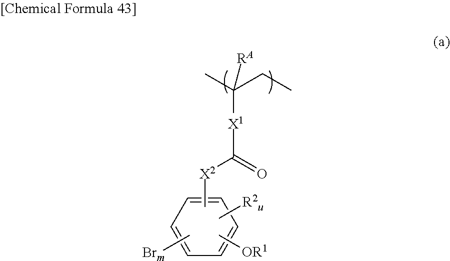

(in the formula (a), R^{A} is a hydrogen atom or a methyl group; R¹ is a hydrogen atom or an acid-unstable group; R² is a linear, branched, or cyclic alkyl group having 1 to 6 carbon atoms or a halogen atom other than bromine; X¹ is a single bond or a phenylene group, or a linear, branched, or cyclic alkylene group having 1 to 12 carbon atoms which may contain an ester group or a lactone ring; X² is —O—, —O—CH₂—, or —NH—; m is an integer of 1 to 4; and n is an integer of 0 to 3).

A resist composition which generates an acid by exposure and has solubility in a developer changed by an action of the acid, the resist composition including:
a base material component (A) whose solubility in a developer is changed by an action of an acid and a fluorine additive component (F) which exhibits decomposability in an alkaline developer,
the fluorine additive component (F) includes a fluororesin component (F1) having a constituent unit (f1) containing a base dissociable group and a constituent unit (f2) containing a group represented by the following general formula (f2-r-1):

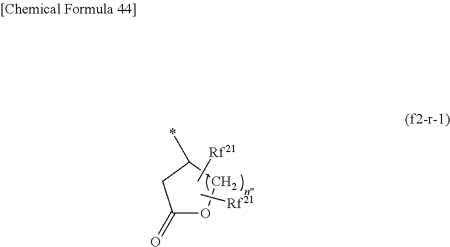

[in the formula (f2-r-1), Rf²¹ each independently represents a hydrogen atom, an alkyl group, an alkoxy group, a hydroxyl group, a hydroxyalkyl group, or a cyano group; n″ is an integer of 0 to 2; and * is a bond].

The structural unit (f1) includes a structural unit represented by the following general formula (f1-1) or a structural unit represented by the following general formula (f1-2):

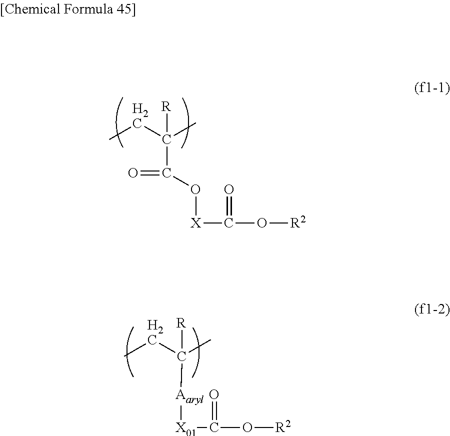

[in the formulas (f1-1) and (f1-2), R's each independently represent a hydrogen atom, an alkyl group having 1 to 5 carbon atoms, or a halogenated alkyl group having 1 to 5 carbon atoms; X is a divalent linking group having no acid-dissociable site; A_{aryl} is a divalent aromatic cyclic group which may have a substituent; X₀₁ is a single bond or a divalent linking group; and R² is each independently an organic group having a fluorine atom].

Examples of the coating, the coating solution, and the coating composition include the followings.

Coatings containing metal oxo-hydroxo networks with organic ligands by metal-carbon and/or metal-carboxylate bonds.

Inorganic oxo/hydroxo based compositions.

A coating solution including: an organic solvent; a first organometallic composition represented by the formula R_{z}SnO_{(2-(2/2)-(x/2)}(OH)ₓ (wherein 0<z≤2 and 0<(z+x)≤4), the formula R′ₙSnX₄₋ₙ (wherein n=1 or 2), or a mixture thereof, wherein R and R′ are each independently a hydrocarbyl group having 1 to 31 carbon atoms, and X is a ligand having a hydrolysable bond to Sn or a combination thereof; and a hydrolysable metal compound represented by the formula MX′ᵥ (wherein M is a metal selected from Groups 2 to 16 of the Periodic Table of the Elements, v is a number from 2 to 6, and X′ is a ligand having a hydrolysable M-X bond or a combination thereof).

A coating solution containing an organic solvent and a first organometallic compound represented by a formula RSn_{(3/2-x/2)}(OH)ₓ (wherein 0<x<3), wherein the solution contains about 0.0025M to about 1.5M of tin and R is an alkyl or cycloalkyl group having 3 to 31 carbon atoms and the alkyl or cycloalkyl group is bonded to the tin at a secondary or tertiary carbon atom.

An inorganic pattern formation precursor aqueous solution including a mixture of water, a metal suboxide cation, a polyatomic inorganic anion, and a radiation sensitive ligand containing a peroxide group.

The exposure is performed through a mask (reticle) for forming a predetermined pattern, and for example, i-ray, KrF excimer laser, ArF excimer laser, EUV (extreme ultraviolet ray), or EB (electron beam) is used, but the resist underlayer film-forming composition of the present application is preferably applied for EB (electron beam) or EUV (extreme ultraviolet ray) exposure, and is preferably applied for EUV (extreme ultraviolet ray) exposure. An alkaline developer is used for development, and the development temperature is selected from 5° C. to 50° C. and the development time from 10 seconds to 300 seconds. Examples of the alkaline developer include aqueous solutions of inorganic alkalis such as sodium hydroxide, potassium hydroxide, sodium carbonate, sodium silicate, sodium metasilicate, and ammonia water, primary amine such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, and cyclic amines such as pyrrole and piperidine. In addition, appropriate amounts of alcohols such as isopropyl alcohol and surfactants such as nonionic surfactants may be added to the above aqueous alkali solutions. Of these developers, quaternary ammonium salts are preferred, and tetramethylammonium hydroxide and choline are more preferred. In addition, surfactants and other agents may be added to these developers. A method of developing a photoresist with an organic solvent such as butyl acetate instead of an alkaline developer may be used to develop a portion of the photoresist where the alkali dissolution rate is not improved. Through the above steps, a substrate on which the resist is patterned can be produced.

Next, the resist underlayer film is dry-etched using the formed resist pattern as a mask. At that time, when the inorganic film is formed on the surface of the used semiconductor substrate, the surface of the inorganic film is exposed. When the inorganic film is not formed on the surface of the used semiconductor substrate, the surface of the semiconductor substrate is exposed. The substrate is then processed by a method known per se (dry etching or the like) to produce a semiconductor device.

### EXAMPLES

The following examples are provided to illustrate the present invention in detail, but the invention is not limited to these examples.

The weight average molecular weight of the polymers shown in the following Synthesis Examples 1 to 10 and Comparative Synthesis Example 1 in the present specification is the result of measurement by gel permeation chromatography (hereinafter, it is abbreviated as GPC). For the measurement, a GPC apparatus manufactured by Tosoh Corporation was used, and measurement conditions and the like are as follows.
GPC column: TSKgel Super-Multipore HZ-N (two columns)
Column temperature: 40° C.
Solvent: tetrahydrofuran (THF)
Flow rate: 0.35 ml/min
Standard sample: polystyrene (manufactured by Tosoh Corporation)

### Synthesis Example 1

In a reaction vessel, 7.00 g of EPICLON HP-4770 (trade name) (manufactured by DIC Corporation), 1.92 g of 5,5-diethylbarbituric acid (manufactured by Tatsuyama Kasei Co., Ltd.), 1.43 g of 3,5-diiodosalicylic acid (manufactured by Tokyo Chemical Industry Co., Ltd.), and 0.31 g of tetrabutylphosphonium bromide (manufactured by Hokko Chemical Industry Co., Ltd.) were added to 49.10 g of propylene glycol monomethyl ether and dissolved. The reaction vessel was purged with nitrogen, and then a reaction was allowed to proceed at 140° C. for 24 hours to obtain a solution containing polymer 1. As a result of GPC analysis, the obtained polymer 1 had a weight average molecular weight of 3,200 and a dispersion degree of 3.7 in terms of standard polystyrene. The structure present in the polymer 1 is represented by the following formula.

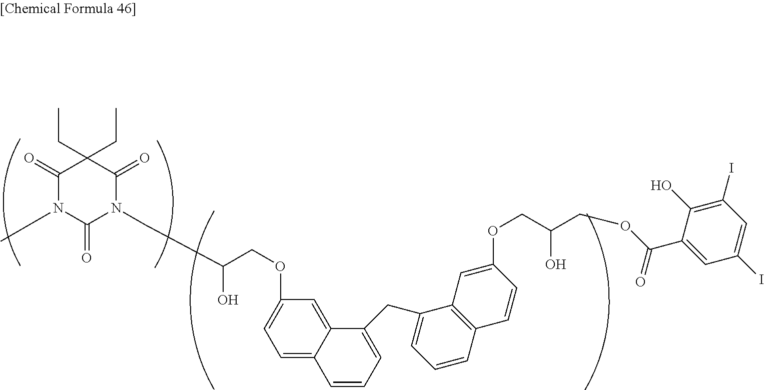

### Synthesis Example 2

In a reaction vessel, 25.00 g of EPICLON WR-600 (propylene glycol monomethyl ether solution manufactured by DIC Corporation), 2.46 g of 5,5-diethylbarbituric acid (manufactured by Tatsuyama Kasei Co., Ltd.), 1.84 g of 3,5-diiodosalicylic acid (manufactured by Tokyo Chemical Industry Co., Ltd.), and 0.40 g of tetrabutylphosphonium bromide (manufactured by Hokko Chemical Industry Co., Ltd.) were added to 11.21 g of propylene glycol monomethyl ether and dissolved. The reaction vessel was purged with nitrogen, and then a reaction was allowed to proceed at 140° C. for 24 hours to obtain a solution containing polymer 2. As a result of GPC analysis, the obtained polymer 2 had a weight average molecular weight of 4,900 and a dispersion degree of 3.5 in terms of standard polystyrene.

### Synthesis Example 3

In a reaction vessel, 4.50 g of EPICLON HP-4770 (trade name) (manufactured by DIC Corporation), 1.83 g of 5,5-diethylbarbituric acid (manufactured by Tatsuyama Kasei Co., Ltd.), 0.33 g of trans-cinnamic acid (manufactured by Tokyo Chemical Industry Co., Ltd.), and 0.28 g of tetrabutylphosphonium bromide (manufactured by Hokko Chemical Industry Co., Ltd.) were added to 85.54 g of propylene glycol monomethyl ether and dissolved. The reaction vessel was purged with nitrogen, and then a reaction was allowed to proceed at 140° C. for 24 hours to obtain a solution containing polymer 3. As a result of GPC analysis, the obtained polymer 3 had a weight average molecular weight of 3,400 and a dispersion degree of 3.2 in terms of standard polystyrene. The structure present in the polymer 3 is represented by the following formula.

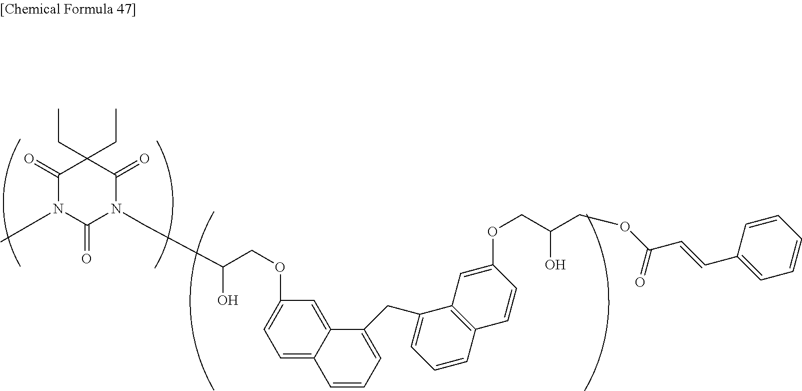

### Synthesis Example 4

In a reaction vessel, 6.00 g of EPICLON HP-4770 (trade name) (manufactured by DIC Corporation), 2.30 g of 5,5-diethylbarbituric acid (manufactured by Tatsuyama Kasei Co., Ltd.), 0.65 g of trans-cinnamic acid (manufactured by Tokyo Chemical Industry Co., Ltd.), and 0.37 g of tetrabutylphosphonium bromide (manufactured by Hokko Chemical Industry Co., Ltd.) were added to 83.97 g of propylene glycol monomethyl ether and dissolved. The reaction vessel was purged with nitrogen, and then a reaction was allowed to proceed at 140° C. for 24 hours to obtain a solution containing polymer 4. As a result of GPC analysis, the obtained polymer 4 had a weight average molecular weight of 4,000 and a dispersion degree of 3.4 in terms of standard polystyrene. The structure present in the polymer 4 is represented by the following formula.

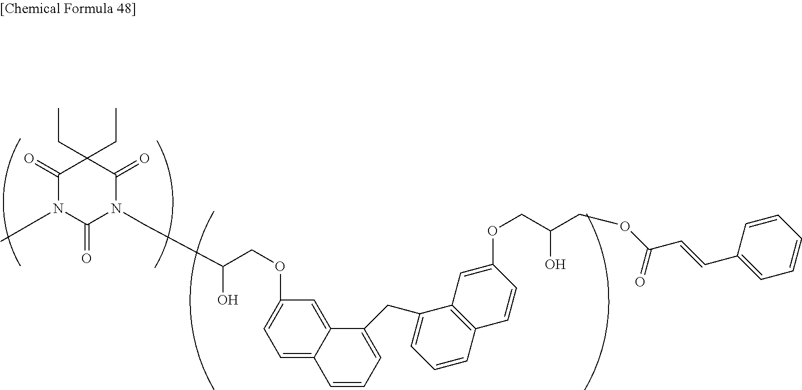

### Synthesis Example 5

In a reaction vessel, 7.00 g of EPICLON HP-4770 (trade name) (manufactured by DIC Corporation), 2.53 g of 5,5-diethylbarbituric acid (manufactured by Tatsuyama Kasei Co., Ltd.), 1.02 g of trans-cinnamic acid (manufactured by Tokyo Chemical Industry Co., Ltd.), and 0.44 g of tetrabutylphosphonium bromide (manufactured by Hokko Chemical Industry Co., Ltd.) were added to 76.87 g of propylene glycol monomethyl ether and dissolved. The reaction vessel was purged with nitrogen, and then a reaction was allowed to proceed at 140° C. for 24 hours to obtain a solution containing polymer 5. As a result of GPC analysis, the obtained polymer 5 had a weight average molecular weight of 4,300 and a dispersion degree of 3.4 in terms of standard polystyrene. The structure present in the polymer 5 is represented by the following formula.

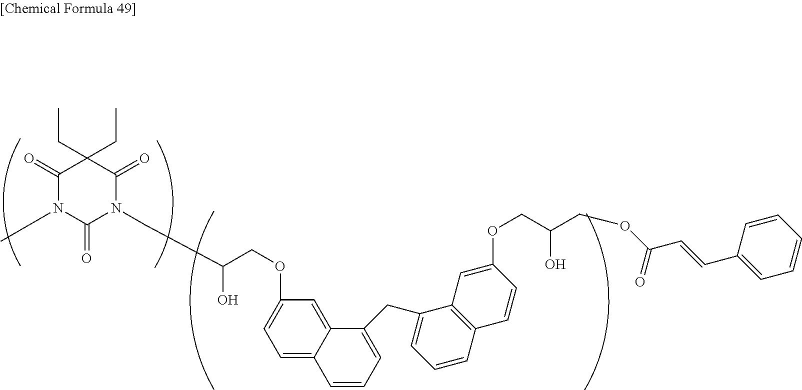

### Synthesis Example 6

In a reaction vessel, 16.00 g of EPICLON WR-600 (propylene glycol monomethyl ether solution manufactured by DIC Corporation), 1.66 g of 5,5-diethylbarbituric acid (manufactured by Tatsuyama Kasei Co., Ltd.), 0.30 g of trans-cinnamic acid (manufactured by Tokyo Chemical Industry Co., Ltd.), and 0.26 g of tetrabutylphosphonium bromide (manufactured by Hokko Chemical Industry Co., Ltd.) were added to 76.03 g of propylene glycol monomethyl ether and dissolved. The reaction vessel was purged with nitrogen, and then a reaction was allowed to proceed at 140° C. for 24 hours to obtain a solution containing polymer 6. As a result of GPC analysis, the obtained polymer 6 had a weight average molecular weight of 4,500 and a dispersion degree of 2.8 in terms of standard polystyrene.

### Synthesis Example 7

In a reaction vessel, 20.00 g of EPICLON WR-600 (propylene glycol monomethyl ether solution manufactured by DIC Corporation), 1.97 g of 5,5-diethylbarbituric acid (manufactured by Tatsuyama Kasei Co., Ltd.), 0.56 g of trans-cinnamic acid (manufactured by Tokyo Chemical Industry Co., Ltd.), and 0.32 g of tetrabutylphosphonium bromide (manufactured by Hokko Chemical Industry Co., Ltd.) were added to 66.22 g of propylene glycol monomethyl ether and dissolved. The reaction vessel was purged with nitrogen, and then a reaction was allowed to proceed at 140° C. for 24 hours to obtain a solution containing polymer 7. As a result of GPC analysis, the obtained polymer 7 had a weight average molecular weight of 4,500 and a dispersion degree of 2.8 in terms of standard polystyrene.

### Synthesis Example 8

In a reaction vessel, 20.00 g of EPICLON WR-600 (propylene glycol monomethyl ether solution manufactured by DIC Corporation), 1.85 g of 5,5-diethylbarbituric acid (manufactured by Tatsuyama Kasei Co., Ltd.), 0.74 g of trans-cinnamic acid (manufactured by Tokyo Chemical Industry Co., Ltd.), and 0.32 g of tetrabutylphosphonium bromide (manufactured by Hokko Chemical Industry Co., Ltd.) were added to 66.85 g of propylene glycol monomethyl ether and dissolved. The reaction vessel was purged with nitrogen, and then a reaction was allowed to proceed at 140° C. for 24 hours to obtain a solution containing polymer 8. As a result of GPC analysis, the obtained polymer 8 had a weight average molecular weight of 3,700 and a dispersion degree of 2.6 in terms of standard polystyrene.

### Synthesis Example 9

In a reaction vessel, 3.17 g of EPICLON HP-4770 (trade name) (manufactured by DIC Corporation), 1.22 g of 5,5-diethylbarbituric acid (manufactured by Tatsuyama Kasei Co., Ltd.), 0.52 g of 9-anthracene carboxylic acid (manufactured by Tokyo Chemical Industry Co., Ltd.), and 0.10 g of tetrabutylphosphonium bromide (manufactured by Hokko Chemical Industry Co., Ltd.) were added to dissolved in 45.00 g of propylene glycol monomethyl ether. The reaction vessel was purged with nitrogen, and then a reaction was allowed to proceed at 140° C. for 24 hours to obtain a solution containing polymer 9. As a result of GPC analysis, the obtained polymer 9 had a weight average molecular weight of 6,000 and a dispersion degree of 3.6 in terms of standard polystyrene.

### Synthesis Example 10

In a reaction vessel, 11.08 g of EPICLON WR-600 (propylene glycol monomethyl ether solution manufactured by DIC Corporation), 1.09 g of 5,5-diethylbarbituric acid (manufactured by Tatsuyama Kasei Co., Ltd.), 0.46 g of 9-anthracene carboxylic acid (manufactured by Tokyo Chemical Industry Co., Ltd.), and 0.09 g of tetrabutylphosphonium bromide (manufactured by Hokko Chemical Industry Co., Ltd.) were added to 37.27 g of propylene glycol monomethyl ether and dissolved. The reaction vessel was purged with nitrogen, and then a reaction was allowed to proceed at 140° C. for 24 hours to obtain a solution containing polymer 10. As a result of GPC analysis, the obtained polymer 10 had a weight average molecular weight of 6,300 and a dispersion degree of 2.9 in terms of standard polystyrene.

### Comparative Synthesis Example 1

In a reaction vessel, 100.00 g of monoallyl diglycidyl isocyanuric acid (manufactured by Shikoku Chemicals Corporation), 66.4 g of 5,5-diethylbarbituric acid (manufactured by Tatsuyama Kasei Co., Ltd.), and 4.1 g of benzyltriethylammonium chloride were added to 682.00 g of propylene glycol monomethyl ether and dissolved. The reaction vessel was purged with nitrogen, and then a reaction was allowed to proceed at 130° C. for 24 hours to obtain a solution containing comparative polymer 1. As a result of GPC analysis, the obtained comparative polymer 1 had a weight average molecular weight of 6,800 and a dispersion degree of 4.8 in terms of standard polystyrene. The structure present in the comparative polymer 1 is represented by the following formula.

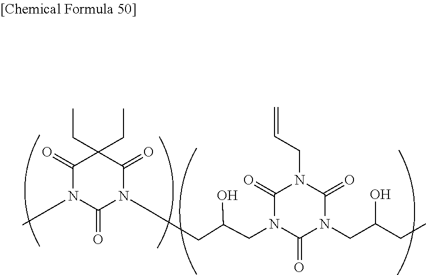

### <Preparation of Resist Underlayer Film>

### Examples and Comparative Examples

Each of the polymers obtained in Synthesis Examples 1 to 10 and Comparative Synthesis Example 1 was mixed with a crosslinking agent, a curing catalyst, and a solvent in the proportions shown in Tables 1 and 2. The resultant mixture was filtered through a fluoroplastic filter with a pore size of 0.1 μm, to prepare a solution of each of the resist underlayer film-forming compositions.

In Tables 1 and 2, tetramethoxymethyl glycoluril is abbreviated as PL-LI; Imidazo[4,5-d]imidazole-2,5(1H,3H)-dione, tetrahydro-1,3,4,6-tetrakis[(2-methoxy-1-methylethoxy)methyl]- is abbreviated as PGME-PL; pyridinium-p-hydroxybenzenesulfonic acid is abbreviated as PyPSA; surfactant is abbreviated as R-30 N; propylene glycol monomethyl ether acetate is abbreviated as PGMEA; and propylene glycol monomethyl ether is abbreviated as PGME. The amount of each of the components incorporated was shown in part(s) by mass.

TABLE 1

| | | Crosslinking | Curing | | |
|---|---|---|---|---|---|
| | Polymer | agent | catalyst | Solvent | |
| Example 1 | Synthesis Example 1 | PGME-PL | PyPSA | PGME | PGMEA |
| (parts by mass) | 0.113 | 0.031 | 0.003 | 70 | 30 |
| Example 2 | Synthesis Example 2 | PGME-PL | PyPSA | PGME | PGMEA |
| (parts by mass) | 0.111 | 0.031 | 0.003 | 70 | 30 |
| Example 3 | Synthesis Example 3 | PGME-PL | PyPSA | PGME | PGMEA |
| (parts by mass) | 0.105 | 0.029 | 0.003 | 70 | 30 |
| Example 4 | Synthesis Example 4 | PGME-PL | PyPSA | PGME | PGMEA |
| (parts by mass) | 0.105 | 0.029 | 0.003 | 70 | 30 |
| Example 5 | Synthesis Example 5 | PGME-PL | PyPSA | PGME | PGMEA |
| (parts by mass) | 0.105 | 0.029 | 0.003 | 70 | 30 |
| Example 6 | Synthesis Example 6 | PGME-PL | PyPSA | PGME | PGMEA |
| (parts by mass) | 0.105 | 0.029 | 0.003 | 70 | 30 |
| Example 7 | Synthesis Example 7 | PGME-PL | PyPSA | PGME | PGMEA |
| (parts by mass) | 0.105 | 0.029 | 0.003 | 70 | 30 |
| Example 8 | Synthesis Example 8 | PGME-PL | PyPSA | PGME | PGMEA |
| (parts by mass) | 0.105 | 0.029 | 0.003 | 70 | 30 |
| Example 9 | Synthesis Example 9 | PGME-PL | PyPSA | PGME | PGMEA |
| (parts by mass) | 0.105 | 0.029 | 0.003 | 70 | 30 |
| Example 10 | Synthesis Example 10 | PGME-PL | PyPSA | PGME | PGMEA |
| (parts by mass) | 0.105 | 0.029 | 0.003 | 70 | 30 |

TABLE 2

| | | Crosslinking | Curing | | | |
|---|---|---|---|---|---|---|
| | Polymer | agent | catalyst | Surfactant | Solvent | |
| Comparative | Comparative | PL-LI | PyPSA | R-30N | PGME | PGMEA |
| Example 1 | Synthesis | | | | | |
| | Example 1 | | | | | |
| (parts by mass) | 0.149 | 0.037 | 0.003 | 0.001 | 70 | 30 |

### (Elution Test in Photoresist Solvent)

Each of the resist underlayer film-forming compositions of Examples 1 to 10 and Comparative Example 1 was applied onto a silicon wafer using a spinner. The silicon wafer was baked on a hot plate at 205° C. for 60 seconds to obtain a film having a film thickness of 4 nm. These resist underlayer films were immersed in a mixed solution of propylene glycol monomethyl ether/propylene glycol monomethyl ether=70/30, which is a solvent used for the photoresist. When the film thickness change 10 was less than 5 Å, the resist underlayer films were evaluated as good; and when the film thickness change was 5 Å or more, the resist underlayer films were evaluated as poor. The results are shown in Table 3.

TABLE 3

| | Elution test |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Comparative Example 1 | Good |

### (Evaluation of Resist Patterning)

### [Test of Resist Pattern Formation by Electron Beam Lithography System]

Each of the resist underlayer film-forming compositions was applied onto a silicon wafer using a spinner. The silicon wafer was baked on a hot plate at 205° C. for 60 seconds to obtain a resist underlayer film having a film thickness of 4 nm. An EUV positive resist solution was spin-coated on the resist underlayer film, and heated at 130° C. for 60 seconds to form an EUV resist film. The resist film was exposed under the predetermined conditions using an electron beam lithography system (ELS-G130). After the exposure, the film was baked (PEB) at 90° C. for 60 seconds, cooled on a cooling plate to room temperature. The cooled film was subjected to paddle development for 30 seconds using a 2.38% aqueous tetramethylammonium hydroxide solution (trade name NMD-3 manufactured by Tokyo Ohka Kogyo Co., Ltd.) as a photoresist developer. A resist pattern having a line size of 16 nm to 28 nm was formed. A scanning electron microscope (CG4100 manufactured by Hitachi High-Tech Corporation) was used for measuring the length of the resist pattern.

The photoresist patterns thus obtained were evaluated for the formation of 22 nm line-and-space (L/S). Formation of 22 nm L/S pattern was confirmed in Examples 1 to 2, Example 4, and Example 7. In addition, the amount of charge that formed 22 nm line/44 nm pitch (line and space (L/S=1/1)) was defined as the optimum irradiation energy, and the irradiation energy (μC/cm²) and LWR at that time are shown in Table 4. In Examples 1 and 2, Example 4, and Example 7, improvement in LWR and minimum CD size were confirmed as compared with Comparative Example 1.

TABLE 4

| | Irradiation energy | Minimum CD size | LWR |
|---|---|---|---|
| | (uC/cm²) | (nm) | (nm) |
| Example 1 | 455 | 18.8 | 3.13 |
| Example 2 | 459 | 18.9 | 3.13 |
| Example 4 | 446 | 18.4 | 3.20 |
| Example 7 | 453 | 18.2 | 3.24 |
| Comparative Example 1 | 457 | 19.3 | 3.26 |

### INDUSTRIAL APPLICABILITY

The resist underlayer film-forming composition according to the present invention can provide a composition for forming a resist underlayer film capable of forming a desired resist pattern, a method for producing a substrate with a resist pattern using the resist underlayer film-forming composition, and a method for producing a semiconductor device.

1. A resist underlayer film-forming composition comprising
a solvent and
a reaction product of a compound (A) represented by the following formula (100): 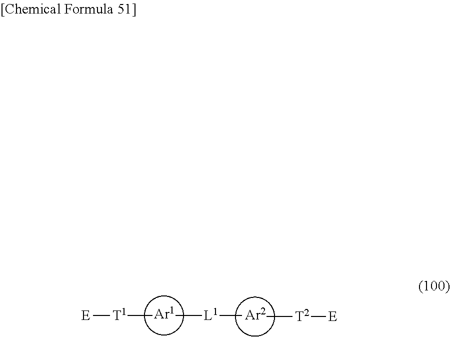
(in the formula (100), Ar¹ and Ar² each independently represent an optionally substituted aromatic ring having 6 to 40 carbon atoms, and at least one of Ar¹ and Ar² is a naphthalene ring; L¹ represents a single bond, an optionally substituted alkylene group having 1 to 10 carbon atoms, or an optionally substituted alkenylene group having 2 to 10 carbon atoms; T¹ and T² each independently represent a single bond, an ester bond, or an ether bond; and E represents an epoxy group) with a compound (B) containing at least two groups having reactivity with an epoxy group.

2. The resist underlayer film-forming composition according to claim 1, wherein the compound (B) contains a heterocyclic ring structure or an aromatic ring structure having 6 to 40 carbon atoms.

3. The resist underlayer film-forming composition according to claim 1, wherein the compound (B) is represented by the following formula (101): 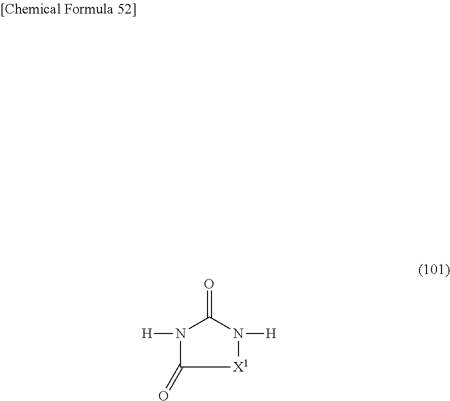
(in the formula (101), X¹ is represented by the following formula (2), formula (3), formula (4), or formula (0): 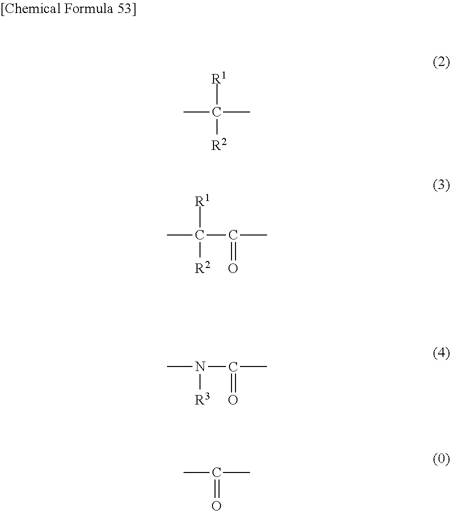
(in the formulae (2), (3), (4) and (0), R¹ and R² each independently represent a hydrogen atom, a halogen atom, an alkyl group having 1 to 10 carbon atoms, an alkenyl group having 2 to 10 carbon atoms, a benzyl group, or a phenyl group, and the alkyl group having 1 to 10 carbon atoms, the alkenyl group having 2 to 10 carbon atoms, the benzyl group, and the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 10 carbon atoms; and R¹ and R² may be bonded to each other to form a ring having 3 to 10 carbon atoms; R³ represent a halogen atom, an alkyl group having 1 to 10 carbon atoms, an alkenyl group having 2 to 10 carbon atoms, a benzyl group, or a phenyl group, and the phenyl group may be substituted with a group selected from the group consisting of an alkyl group having 1 to 10 carbon atoms, a halogen atom, an alkoxy group having 1 to 10 carbon atoms, a nitro group, a cyano group, a hydroxy group, and an alkylthio group having 1 to 10 carbon atoms).

4. The resist underlayer film-forming composition according to claim 1, wherein the reaction product has a terminal comprising a structure represented by the following formula (102): 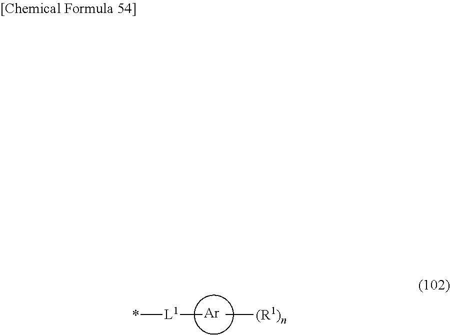
(in the formula (102), Ar represents an optionally substituted aromatic ring having 6 to 40 carbon atoms; L¹ represents an ester bond, an ether bond, or an optionally substituted alkenylene group having 2 to 10 carbon atoms; n quantity of R¹ independently represent a group selected from the group consisting of a hydroxy group, a halogen atom, a carboxy group, a nitro group, a cyano group, a methylenedioxy group, an acetoxy group, a methylthio group, an amino group, an optionally substituted alkyl group having 1 to 10 carbon atoms, and an optionally substituted alkoxy group having 1 to 10 carbon atoms; n represents an integer of 0 to 5; and * represents a bonding site to the reaction product).

5. The resist underlayer film-forming composition according claim 1, further comprising an acid generator.

6. The resist underlayer film-forming composition according to claim 1, further comprising a crosslinking agent.

7. The resist underlayer film-forming composition according to claim 1, which is for an extreme ultraviolet (EUV) exposure process.

8. A resist underlayer film, which is a baked product of a coating film of the resist underlayer film-forming composition according to claim 1.

9. A method for producing a patterned substrate, comprising the steps of:
applying the resist underlayer film-forming composition according to claim 1 onto a semiconductor substrate followed by baking, to form a resist underlayer film;
applying a resist onto the resist underlayer film followed by baking, to form a resist film;
exposing the semiconductor substrate coated with the resist underlayer film and the resist; and

10. A method for producing a semiconductor device, comprising the steps of:
forming a resist underlayer film of the resist underlayer film-forming composition of claim 1 on a semiconductor substrate;
forming a resist film on the resist underlayer film;
forming a resist pattern by irradiating the resist film with a light or electron beam followed by development;
forming a patterned resist underlayer film by etching the resist underlayer film through the formed resist pattern; and
processing the semiconductor substrate with the patterned resist underlayer film.
